(19) United States
(12) Patent Application Publication
(10) Pub. No.: US 2025/0248236 A1
(43) Pub. Date: Jul. 31, 2025

(54) DISPLAY DEVICE

(71) Applicant: Samsung Display Co., Ltd., Yongin-Si (KR)

(72) Inventor: Sang Min HONG, Yongin-si (KR)

(21) Appl. No.: 18/818,587

(22) Filed: Aug. 29, 2024

(30) Foreign Application Priority Data
Jan. 31, 2024 (KR) 10-2024-0014565

(51) Int. Cl. H10K 59/126; H10K 59/122; H10K 59/124; H10K 59/38; H10K 59/80

(52) U.S. Cl. CPC H10K 59/126; H10K 59/122; H10K 59/124; H10K 59/38; H10K 59/873

(57) ABSTRACT

A display device includes a first pixel and a second pixel spaced apart from each other. Each of the first pixel and the second pixel includes a plurality of emission areas where light-emitting elements are disposed, a light-blocking layer including a plurality of holes overlapping with the emission areas and disposed between adjacent ones of the emission areas, and a plurality of color filters disposed in the holes of the light-blocking layer and overlapping with the emission areas. The emission areas include first, second, and third emission areas spaced apart from one another. The light-emitting element disposed in the first emission area of the first pixel is located at a lower level than the light-emitting element disposed in the first emission area of the second pixel.

This application claims priority from Korean Patent Application No. 10-2024-0014565 filed on Jan. 31, 2024, in the Korean Intellectual Property Office, the disclosure of which is incorporated herein by reference in its entirety.

### BACKGROUND

### 1. Field of the Disclosure

The present disclosure relates to a display device.

### 2. Description of the Related Art

As the information-oriented society evolves, various demands for display devices are ever increasing. Display devices may be a liquid-crystal display device, a field emission display device, a light-emitting display device, or the like. Light-emitting display devices may include an organic light-emitting display device including organic light-emitting diodes as light-emitting elements, an inorganic light-emitting display device including inorganic light-emitting diodes as light-emitting elements, etc.

Due to the diffusion characteristics of light, the images on a display device can be viewed not only from the front but also from the sides. In order to protect the privacy of a user using a display device, it is necessary to prevent images on the display device from being seen by other people than the user. Accordingly, a broad range of research on viewing angle control is under way.

### SUMMARY

Aspects of the present disclosure provide a display device that can control the viewing angle of high-resolution pixels.

Aspects of the present disclosure also provide a display device with improved process efficiency.

It should be noted that features of the present disclosure are not limited to the above-mentioned features; and other features of the present disclosure will be apparent to those skilled in the art from the following descriptions.

According to an aspect of the present disclosure, there is provided a display device including, a first pixel and a second pixel spaced apart from each other. Each of the first pixel and the second pixel includes a plurality of emission areas where light-emitting elements are disposed, a light-blocking layer including a plurality of holes overlapping with the emission areas and disposed between adjacent ones of the emission areas, and a plurality of color filters disposed in the holes of the light-blocking layer and overlapping with the emission areas. The emission areas include first, second, and third emission areas spaced apart from one another. The light-emitting element disposed in the first emission area of the first pixel is located at a lower level than the light-emitting element disposed in the first emission area of the second pixel.

In an embodiment, a distance between the light-emitting element disposed in the first emission area of the first pixel and the light-blocking layer is greater than a distance between the light-emitting element disposed in the first emission area of the second pixel and the light-blocking layer.

In an embodiment, the holes of the light-blocking layer comprise first, second, and third holes overlapping with the first, second, and third emission areas, respectively. A width of the first hole of the first pixel is smaller than a width of the first hole of the second pixel.

In an embodiment, the display device may further comprise a thin-film transistor layer configured to drive the light-emitting elements, a first protective film disposed on the thin-film transistor layer, and a pixel-defining layer disposed on the first protective film and comprising an opening overlapping with a respective emission area of the emission areas. The first protective film further comprises a first connection opening connected to the opening of the pixel-defining layer in the first pixel.

In an embodiment, each of the light-emitting elements comprises an emissive layer. The emissive layer is disposed in the first connection opening in the first pixel.

In an embodiment, the light-emitting element in the second pixel is disposed on the first protective film.

In an embodiment, the emissive layer in the second pixel is disposed in the opening of the pixel-defining layer.

In an embodiment, each of the light-emitting elements comprises a first electrode, an emissive layer disposed on the first electrode, and a second electrode disposed on the emissive layer. The second electrode covers an inner surface of the first connection opening in the first pixel.

In an embodiment, the display device may further comprise a thin-film encapsulation layer disposed on the second electrode. At least a portion of the thin-film encapsulation layer is disposed in the first connection opening in the first pixel.

In an embodiment, the display device may further comprise a second protective film disposed between the first protective film and the thin-film transistor layer. The second protective film comprises a second connection opening connected to the opening through the first connection opening. Each of the light-emitting elements comprises an emissive layer, and the emissive layer is disposed in the second connection opening in the first pixel.

In an embodiment, the display device may further comprise a thin-film transistor layer configured to drive the light-emitting elements, a first protective film disposed on the thin-film transistor layer, and a pixel-defining layer disposed on the first protective film and comprising an opening overlapping with a respective emission area of the emission areas. The first protective film comprises a valley connected to the opening of the pixel-defining layer in the first pixel.

In an embodiment, each of the light-emitting elements comprises an emissive layer, and the emissive layer is disposed in the valley in the first pixel.

In an embodiment, the color filters comprise a first color filter overlapping with the first emission area, a second color filter overlapping with the second emission area, and a third color filter overlapping with the third emission area.

According to an aspect of the present disclosure, there is provided a display device including a plurality of emission areas where light-emitting elements are disposed, a light-blocking layer including a plurality of holes overlapping with the emission areas and disposed between adjacent ones of the emission areas, and a plurality of color filters disposed in the holes of the light-blocking layer and overlapping with the emission areas. The emission areas include a first emission area and a second emission area spaced apart from each other. The first emission area and the second emission area emit light of a same color. The light-emitting element disposed in the first emission area is located lower than the light-emitting element disposed in the second emission area.

In an embodiment, a distance between the light-emitting element disposed in the first emission area and the light-blocking layer is greater than a distance between the light-emitting element disposed in the second emission area and the light-blocking layer.

In an embodiment, the holes in the light-blocking layer comprise a first hole overlapping with the first emission area and a second hole overlapping with the second emission area. A width of the first hole is smaller than a width of the second hole.

In an embodiment, the display device may further comprise a thin-film transistor layer configured to drive the light-emitting elements, a first protective film disposed on the thin-film transistor layer, and a pixel-defining layer disposed on the first protective film and comprising an opening overlapping with a respective emission area of the emission areas. The first protective film comprises a first connection opening that is overlapping with the first emission area and is connected to the opening of the pixel-defining layer.

In an embodiment, each of the light-emitting elements comprises an emissive layer, and the emissive layer overlapping with the first emission area is disposed in the first connection opening.

In an embodiment, the light-emitting element disposed in the second emission area is disposed on the first protective film.

In an embodiment, the emissive layer overlapping with the second emission area is disposed in the opening of the pixel-defining layer.

In an embodiment, each of the light-emitting elements comprises a first electrode, an emissive layer disposed on the first electrode, and a second electrode disposed on the emissive layer. At least a part of the second electrode overlapping with the first emission area covers an inner surface of the first connection opening.

In an embodiment, the display device may further comprise a thin-film encapsulation layer disposed on the second electrode. At least a portion of the thin-film encapsulation layer overlapping with the first emission area is disposed in the first connection opening.

In an embodiment, the display device may further comprise a second protective film disposed between the first protective film and the thin-film transistor layer. The second protective film comprises a second connection opening connected to the opening through the first connection opening. Each of the light-emitting elements comprises an emissive layer, and the emissive layer overlapping with the first emission area is disposed in the second connection opening.

In an embodiment, the display device may further comprise a thin-film transistor layer configured to drive the light-emitting elements, a first protective film disposed on the thin-film transistor layer, and a pixel-defining layer disposed on the first protective film and comprising an opening overlapping with a respective emission area of the emission areas. The first protective film comprises a valley that is overlapping with the first emission area and is connected to the opening of the pixel-defining layer.

In an embodiment, each of the light-emitting elements comprises an emissive layer, and the emissive layer overlapping with the first emission area is disposed in the valley.

In an embodiment, the color filters comprise a first color filter overlapping with the first emission area and a second color filter overlapping with the second emission area. The first color filter and the second color filter transmit light of a same color.

According to an embodiment of the present disclosure, the viewing angle of high-resolution pixels can be controlled.

According to an embodiment of the present disclosure, the process efficiency of a display device can be improved.

It should be noted that effects of the present disclosure are not limited to those described above and other effects of the present disclosure will be apparent to those skilled in the art from the following descriptions.

### BRIEF DESCRIPTION OF THE DRAWINGS

The above and other aspects and features of the present disclosure will become more apparent by describing in detail exemplary embodiments thereof with reference to the attached drawings.

FIG. 1 is a perspective view of an electron device according to an exemplary embodiment of the present disclosure.

FIG. 2 is a perspective view showing a foldable electronic device according to an embodiment of the present disclosure when it is folded.

FIG. 3 is a perspective view showing the foldable electronic device of FIG. 2 when it is unfolded.

FIG. 4 is a perspective view showing a display device included in an electron device according to an embodiment of the present disclosure.

FIG. 5 is a cross-sectional view of the display device of FIG. 4 seen from the side.

FIG. 6 is a plan view showing a display layer of a display device according to an embodiment of the present disclosure.

FIG. 7 is a plan view showing a touch sensing layer of a display device according to an embodiment of the present disclosure.

FIG. 8 is a plan view showing arrangements of emission areas and touch electrodes in a display area of a display device according to an embodiment.

FIG. 9 is a plan view showing arrangement of color filters in a display area of a display device according to an embodiment.

FIG. 10 is a plan view showing an arrangement of normal pixels and privacy pixels in a display area of a display device according to an embodiment.

FIG. 11 is a cross-sectional view taken along line X1-X1′ in FIG. 10.

FIG. 12 is a cross-sectional view taken along line X2-X2′ of FIG. 10.

FIG. 13 is a cross-sectional view, taken along lines X3-X3′ and X4-X4′ in FIG. 10.

FIG. 14 is a cross-sectional view showing an emission area in a privacy pixel of a display device according to an embodiment.

FIG. 15 is a cross-sectional view showing an emission area of a privacy pixel of a display device according to an embodiment.

FIG. 16 is a cross-sectional view showing a privacy pixel in a display device according to an embodiment of the present disclosure.

FIG. 17 is a plan view showing arrangement of color filters in a display area of a display device according to an embodiment.

FIG. 18 is a plan view showing arrangement of color filters in a display area of a display device according to an embodiment.

### DETAILED DESCRIPTION OF THE EMBODIMENTS

The inventive concept will now be described more fully hereinafter with reference to the accompanying drawings, in which embodiments of the inventive concept are shown. The inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art.

It will also be understood that when a layer is referred to as being “on” another layer or substrate, it can be directly on the other layer or substrate, or intervening layers may also be present.

The same reference numbers indicate the same components throughout the specification.

Hereinafter, embodiments of the present disclosure will be described in detail with reference to the accompanying drawings.

Hereinafter, exemplary embodiments of the present disclosure will be described in detail with reference to the accompanying drawings.

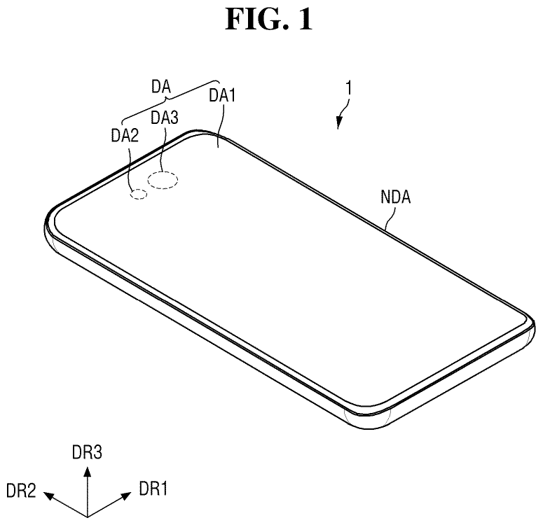

FIG. 1 is a perspective view of an electron device 1 according to an exemplary embodiment of the present disclosure.

Referring to FIG. 1, the electron device 1 displays a moving image or a still image. The electron device 1 may refer to any electronic device that provides a display screen. For example, the electron device 1 may include a television set, a laptop computer, a monitor, an electronic billboard, the Internet of Things devices, a mobile phone, a smart phone, a tablet personal computer (PC), an electronic watch, a smart watch, a watch phone, a head-mounted display device, a mobile communications terminal, an electronic notebook, an electronic book, a portable multimedia player (PMP), a navigation device, a game console and a digital camera, a camcorder, etc.

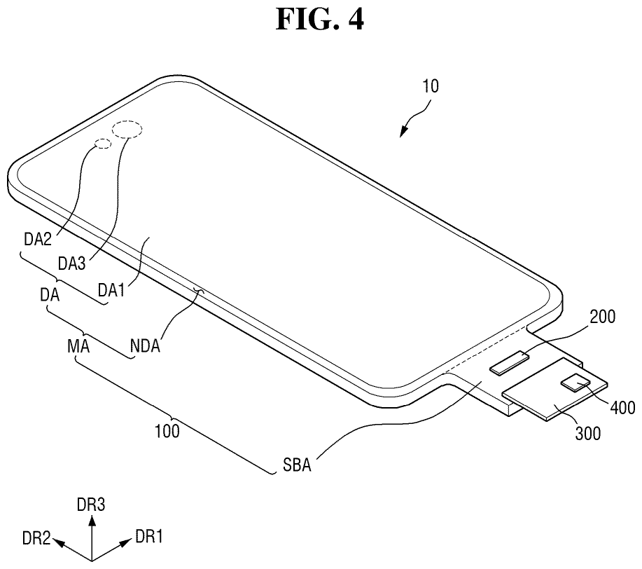

The electron device 1 may include a display device 10 (see FIG. 4) for providing a display screen. Examples of the display device may include an inorganic light-emitting diode display device, an organic light-emitting display device, a quantum-dot light-emitting display device, a plasma display device, a field emission display device, etc. In the following description, an organic light-emitting diode display device is employed as an example of the display device, but the present disclosure is not limited thereto. Any other display device may be employed as long as the technical idea of the present disclosure can be equally applied.

The shape of the electron device 1 may be modified in a variety of ways. For example, the electron device 1 may have shapes such as a rectangle with longer lateral sides, a rectangle with longer vertical sides, a square, a quadrangle with rounded corners (vertices), other polygons, a circle, etc. The shape of a display area DA of the electron device 1 may also be similar to the overall shape of the electron device 1. In the example shown in FIG. 1, the electron device 1 has a rectangular shape with the longer sides in a second direction DR2.

The electron device 1 may include the display area DA and a non-display area NDA. In the display area DA, images can be displayed. In the non-display area NDA, images are not displayed. The display area DA may be referred to as an active area, while the non-display area NDA may also be referred to as an inactive area. The display area DA may generally occupy the center of the electron device 1.

The display area DA may include a first display area DA1, a second display area DA2 and a third display area DA3. In the second display area DA2 and the third display area DA3, components for adding a variety of features to the electronic device 1 may be disposed. In other words, the second display area DA2 and the third display area DA3 may be referred to as component areas.

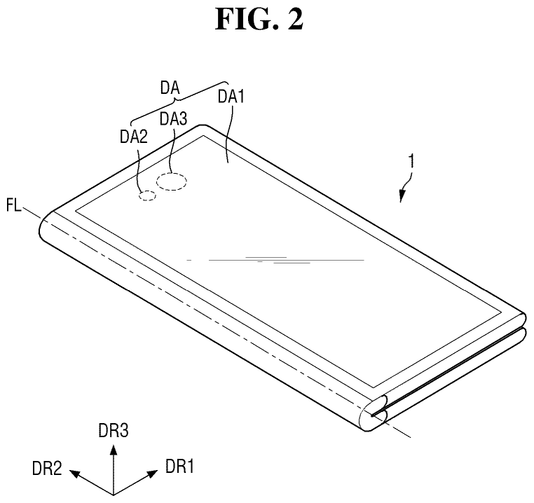

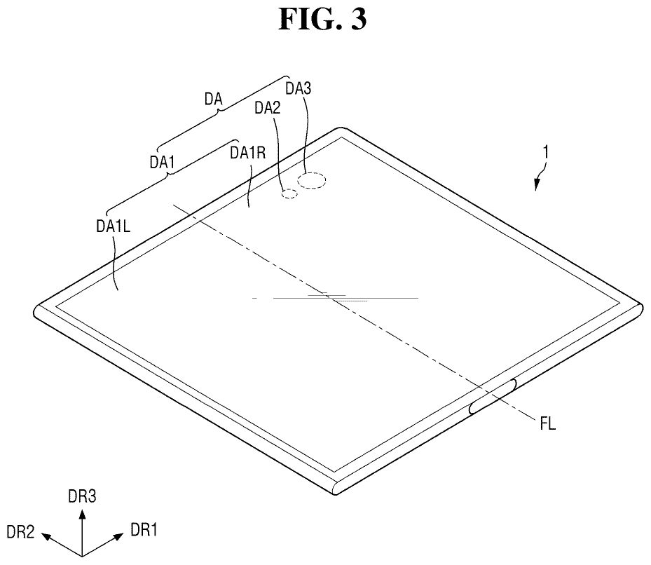

FIG. 2 is a perspective view showing a foldable electronic device 1 according to an embodiment of the present disclosure when it is folded. FIG. 3 is a perspective view showing the foldable electronic device 1 of FIG. 2 when it is unfolded.

Referring to FIGS. 2 and 3, the electronic device 1 according to the embodiment may be a foldable display device. The foldable electronic device 1 may be folded along a folding axis FL. The display area DA may be located on the outer side and/or inner side of the foldable electronic device 1. According to the embodiment of FIGS. 2 and 3, the display area DA is disposed on each of the outer and inner sides of the foldable electronic device 1.

The display area DA may be disposed on the outer side of electronic device 1. The outer surface of the electronic device 1 when it is folded may include the display area DA, and the inner surface of the electronic device 1 when it is unfolded may include the display area DA. The display area DA of the foldable electronic device 1 of FIG. 3 may include a first display area DA1 that occupies most of the display area DA, and a second display area DA2 and a third display area DA3 that occupy a smaller area than the first display area DA1. The first display area DA1 may include a first display portion DA1L and a second display portion DA1R located on both sides of the folding axis FL, respectively. The second display area DA2 and the third display area DA3 may be disposed in an area where the second display portion DA1R is located, but the present disclosure is not limited thereto. According to an embodiment, the second display area DA2 and the third display area DA3 may be located in the area where the first display portion DA1L is located, or one of the second display area DA2 and the third display area DA3 may be located in the first display portion DA1L while the other one may be located in the second display portion DA1R.

As in the example shown in FIGS. 1 to 3, each of the second display area DA2 and the third display area DA3 may have an area smaller than that of the first display area DAL. The second display area DA2 and the third display area DA3 may have different sizes or areas, but the present disclosure is not limited thereto. In the following descriptions, the second display area DA2 has a smaller area than the third display area DA3 in the drawings. Each of the second display area DA2 and the third display area DA3 may be surrounded by the first display area DAL. It is, however, to be understood that the present disclosure is not limited thereto.

FIG. 4 is a perspective view showing the display device 10 included in an electron device according to an embodiment of the present disclosure.

Referring to FIG. 4, the electron device 1 according to the exemplary embodiment of the present disclosure may include the display device 10. The display device 10 may provide a display screen where images are displayed in the electron device 1. The display device 10 may have a shape similar to that of the electronic device 1 when viewed from the top. For example, the display device 10 may have a shape similar to a rectangle having shorter sides in the first direction DR1 and longer sides in the second direction DR2. The corners where the shorter sides in the first direction DR1 meet the longer sides in the second direction DR2 may be rounded with a predetermined curvature. It should be understood, however, that the present disclosure is not limited thereto. The corners may be formed at a right angle. The shape of the display device 10 when viewed from the top is not limited to a quadrangular shape, but may be formed in a shape similar to other polygonal shapes, a circular shape, or an elliptical shape.

The display device 10 may include a display panel 100, a display driver 200, a circuit board 300 and a touch driver 400.

The display panel 100 may include a main area MA and a subsidiary area SBA.

The main area MA may include the display area DA including pixels for displaying images, and the non-display area NDA located around the display area DA. The display area DA may include the first display area DA1, the second display area DA2 and the third display area DA3. The display area DA may output lights from a plurality of emission areas or a plurality of open areas. For example, the display panel 100 may include a pixel circuit including switching elements, a pixel-defining layer that defines the emission areas or the open areas, and self-light-emitting elements.

For example, the self-light-emitting element may include, but is not limited to, at least one of: an organic light-emitting diode including an organic emissive layer, a quantum-dot light-emitting diode (quantum LED) including a quantum-dot emissive layer, an inorganic light-emitting diode (inorganic LED) including an inorganic semiconductor, and a micro light-emitting diode (micro LED).

The non-display area NDA may be located on the outer side of the display area DA. The non-display area NDA may be defined as the edge of the main area MA of the display panel 100. The non-display area NDA may include a gate driver (not shown) that applies gate signals to gate lines, and fan-out lines (not shown) that connect the display driver 200 with the display area DA.

The subsidiary area SBA may be extended from one side of the main area MA. The subsidiary area SUB may include a flexible material that can be bent, folded, or rolled. For example, when the subsidiary area SBA is bent, the subsidiary area SBA may overlap the main area MA in the thickness direction (third direction DR3). The subsidiary area SBA may include pads connected to the display driver 200 and the circuit board 300. According to another exemplary embodiment, the subsidiary area SBA may be eliminated, and the display driver 200 and the pads may be disposed in the non-display area NDA.

The display driver 200 may output signals and voltages for driving the display panel 100. The display driver 200 may supply data voltages to data lines. The display driver 200 may apply a supply voltage to a voltage line and may supply gate control signals to the gate driver. The display driver 200 may be implemented as an integrated circuit (IC) and may be attached on the display panel 100 by a chip-on-glass (COG) technique, a chip-on-plastic (COP) technique, or ultrasonic bonding. For example, the display driver 200 may be disposed in the subsidiary area SBA and may overlap with the main area MA in the thickness direction as the subsidiary area SBA is bent. For another example, the display driver 200 may be mounted on the circuit board 300.

The circuit board 300 may be attached on the pad area of the display panel 100 using an anisotropic conductive film (ACF). Lead lines of the circuit board 300 may be electrically connected to the pads of the display panel 100. The circuit board 300 may be a flexible printed circuit board (FPCB), a printed circuit board (PCB), or a flexible film such as a chip-on-film (COF).

The touch driver 400 may be mounted on the circuit board 300. The touch driver 400 may be connected to a touch sensing unit of the display panel 100. The touch driver 400 may supply a touch driving signal to a plurality of touch electrodes of the touch sensing unit and may sense a change in the capacitance between the plurality of touch electrodes. For example, the touch driving signals may be pulse signals having a predetermined frequency. The touch driver 400 may determine whether there is an input and may find the coordinates of the input based on the amount of the change in the capacitance between the touch electrodes. The touch driver 400 may be implemented as an integrated circuit (IC).

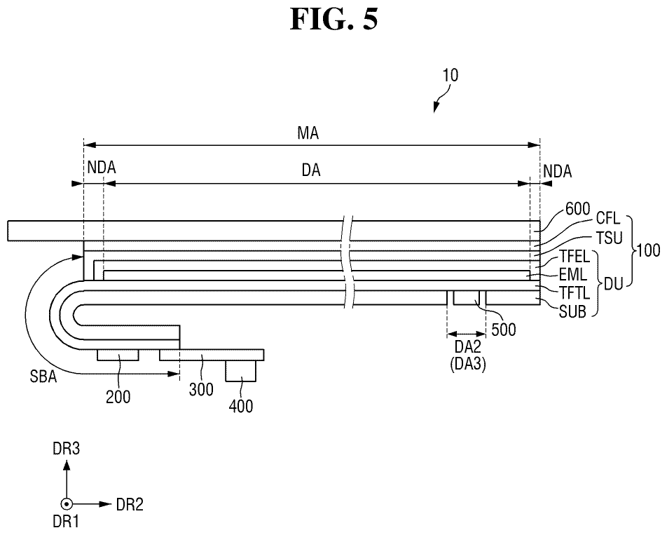

FIG. 5 is a cross-sectional view of the display device of FIG. 4 seen from the side.

Referring to FIG. 5, the display panel 100 may include a display layer DU, a touch sensing layer TSU, and a color filter layer CFL. The display layer DU may include a substrate SUB, a thin-film transistor layer TFTL, an emission material layer EML and an encapsulation layer TFEL.

The substrate SUB may be a base substrate or a base member. The substrate SUB may be a flexible substrate that can be bent, folded, or rolled. For example, the substrate SUB may include, but is not limited to, a polymer resin such as polyimide (PI). According to another exemplary embodiment, the substrate SUB may include a glass material or a metal material.

The thin-film transistor layer TFTL may be disposed on the substrate SUB. The thin-film transistor layer TFTL may include a plurality of thin-film transistors forming pixel circuits of pixels. The thin-film transistor layer TFTL may include gate lines, data lines, voltage lines, gate control lines, fan-out lines for connecting the display driver 200 with the data lines, lead lines for connecting the display driver 200 with the pads, etc. Each of the thin-film transistors may include a semiconductor region, a source electrode, a drain electrode, and a gate electrode. For example, when the gate driver is formed on one side of the non-display area NDA of the display panel 100, the gate driver may include thin-film transistors.

The thin-film transistor layer TFTL may be disposed in the display area DA, the non-display area NDA and the subsidiary area SBA. The thin-film transistors in each of the pixels, the gate lines, the data lines and the voltage lines in the thin-film transistor layer TFTL may be disposed in the display area DA. The gate control lines and the fan-out lines in the thin-film transistor layer TFTL may be disposed in the non-display area NDA. The lead lines of the thin-film transistor layer TFTL may be disposed in the subsidiary area SBA.

The emission material layer EML may be disposed on the thin-film transistor layer TFTL. The emission material layer EML may include a plurality of light-emitting elements each including a first electrode, a second electrode and an emissive layer to emit light, and a pixel-defining layer for defining the pixels. The plurality of light-emitting elements in the emission material layer EML may be disposed in the display area DA.

According to an exemplary embodiment of the present disclosure, the emissive layer may be an organic emissive layer containing an organic material. The emissive layer may include a hole transporting layer, an organic light-emitting layer and an electron transporting layer. When the first electrode receives a voltage and the second electrode receives a cathode voltage through the thin-film transistors on the thin-film transistor layer TFTL, the holes and electrons may move to the organic light-emitting layer through the hole transporting layer and the electron transporting layer, respectively, such that they combine in the organic light-emitting layer to emit light.

According to an embodiment, the light-emitting elements may include quantum-dot light-emitting diodes each including a quantum-dot emissive layer, inorganic light-emitting diodes each including an inorganic semiconductor, or micro light-emitting diodes.

The encapsulation layer TFEL may cover the upper and side surfaces of the emission material layer EML, and can protect the emission material layer EML. The encapsulation layer TFEL may include at least one inorganic layer and at least one organic layer for encapsulating the emission material layer EML.

The touch sensing layer TSU may be disposed on the encapsulation layer TFEL. The touch sensing layer TSU may include a plurality of touch electrodes for sensing a user's touch by capacitive sensing, and touch lines connecting the plurality of touch electrodes with the touch driver 400. For example, the touch sensing layer TSU may sense a user's touch by mutual capacitance sensing or self-capacitance sensing.

For another example, the touch sensing layer TSU may be disposed on a separate substrate disposed on the display layer DU. In such case, the substrate supporting the touch sensing layer TSU may be a base member encapsulating the display layer DU.

The plurality of touch electrodes of the touch sensing layer TSU may be disposed in a touch sensor area overlapping the display area DA. The touch lines of the touch sensing layer TSU may be disposed in a touch peripheral area overlapping the non-display area NDA.

The color filter layer CFL may be disposed on the touch sensing layer TSU. The color filter layer CFL may include a plurality of color filters associated with the plurality of emission areas, respectively. Each of the color filters may selectively transmit light of a particular wavelength and block or absorb lights of other wavelengths. The color filter layer CFL may absorb some of lights introduced from the outside of the display device 10 to reduce the reflection of external light. Accordingly, the color filter layer CFL can prevent distortion of colors due to the reflection of external light.

Since the color filter layer CFL is disposed directly on the touch sensing layer TSU, the display device 10 may require no separate substrate for the color filter layer CFL. Therefore, the thickness of the display device 10 can be relatively small.

In some embodiments, the display device 10 may further include an optical device 500 and a window member 600.

The optical device 500 may be disposed in the second display area DA2 or the third display area DA3. The optical device 500 may output or receive light in infrared, ultraviolet, and visible ranges. For example, the optical device 500 may be an optical sensor that senses light incident on the display device 10, such as a proximity sensor, an illuminance sensor, a camera sensor and an image sensor.

The window member 600 may be disposed on the display panel 100. The window member 600 may cover the display panel 100. The window member 600 may completely cover the display area DA and the non-display area NDA of the display device 10. The shape of the window member 600 may conform to the shape of the display panel 100. The window member 600 may protect the display panel 100 from external shocks and provide an input surface to the user.

The window member 600 may be transparent so that light generated in the display panel 100 can be transmitted. The window member 600 may include glass or plastic material. In some embodiments where the window member 600 includes glass, it may include chemically strengthened glass by ion substitution. According to an embodiment where the window member 600 includes plastic, it may include a polyimide film.

According to some embodiments, the color filter layer CFL is incorporated into the display panel 100, so that the window member 600 may be mounted directly on the display panel 100. For example, an optical member such as a polarizing film may not be disposed on the window member 600 and the display panel 100. Accordingly, the thickness of the display device 10 can be reduced. If the display device 10 is a foldable device, folding stress can be reduced.

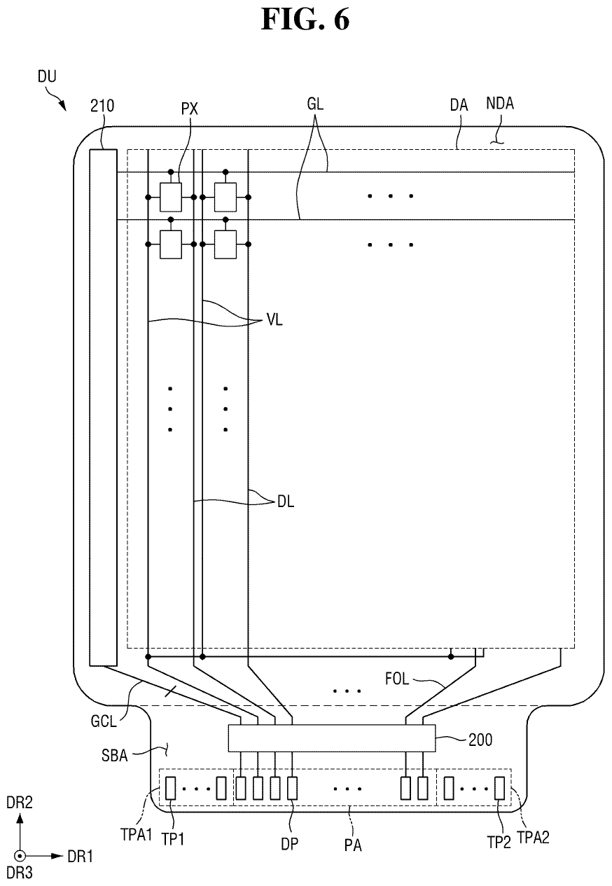

FIG. 6 is a plan view showing a display layer DU of a display device according to an embodiment of the present disclosure.

Referring to FIG. 6, the display layer DU may include a display area DA and a non-display area NDA.

The display area DA may be disposed at the center of display device 100. In the display area DA, a plurality of pixels PX, a plurality of gate lines GL, a plurality of data lines DL and a plurality of voltage lines VL may be disposed. Each of the plurality of pixels PX may be defined as the minimum unit that outputs light.

The plurality of gate lines GL may supply the gate signals received from a gate driver 210 to the plurality of pixels PX. The plurality of gate lines GL may be extended in the first direction DR1 and may be spaced apart from one another in the second direction DR2 intersecting the first direction DR1.

The plurality of data lines DL may supply the data voltages received from the display driver 200 to the plurality of pixels PX. The plurality of data lines DL may be extended in the second direction DR2 and may be spaced apart from one another in the first direction DR1.

The plurality of voltage lines VL may apply the supply voltage received from the display driver 200 to the plurality of pixels PX. The supply voltage may be at least one of a driving voltage, an initialization voltage, a reference voltage and a low-level voltage. The plurality of voltage lines VL may be extended in the second direction DR2 and may be spaced apart from one another in the first direction DR1.

The non-display area NDA may surround the display area DA. In the non-display area NDA, the gate driver 210, fan-out lines FOL, and gate control lines GCL may be disposed. The gate driver 210 may generate a plurality of gate signals based on the gate control signal, and may sequentially supply the plurality of gate signals to the plurality of gate lines GL in a predetermined order.

The fan-out lines FOL may be extended from the display driver 200 to the display area DA. The fan-out lines FOL may supply the data voltage received from the display driver 200 to the plurality of data lines DL.

A gate control line GCL may be extended from the display driver 200 to the gate driver 210. The gate control line GCL may supply the gate control signal received from the display driver 200 to the gate driver 210.

The subsidiary area SBA may include the display driver 200, a pad area PA, and first and second touch pad areas TPA1 and TPA2.

The display driver 200 may output signals and voltages for driving the display panel 100 to the fan-out lines FOL. The display driver 200 may supply data voltages to the data lines DL through the fan-out lines FOL. The data voltages may be applied to the plurality of pixels PX, so that the luminance of the plurality of pixels PX may be controlled. The display driver 200 may supply a gate control signal to the gate driver 210 through the gate control lines GCL.

The pad area PA, the first touch pad area TPA1 and the second touch pad area TPA2 may be disposed at the edge of the subsidiary area SBA. The pad area PA, the first touch pad area TPA1 and the second touch pad area TPA2 may be electrically connected to the circuit board 300 using a material such as an anisotropic conductive film and a self-assembly anisotropic conductive paste (SAP).

The pad area PA may include a plurality of display pads DP. The plurality of display pads DP may be connected to a graphic system through the circuit board 300. The plurality of display pads DP may be connected to the circuit board 300 to receive digital video data and may supply the digital video data to the display driver 200.

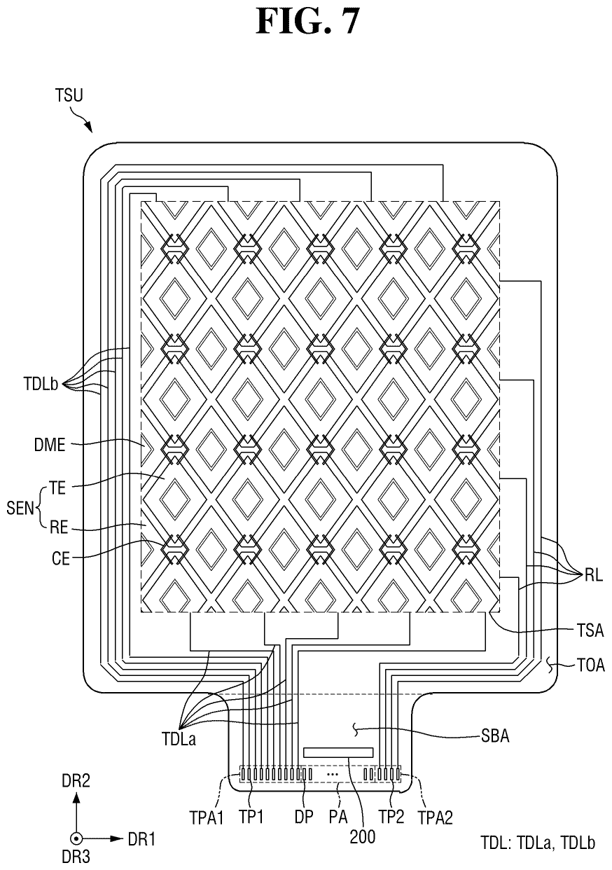

FIG. 7 is a plan view showing a touch sensing layer TSU of a display device according to an embodiment of the present disclosure.

Referring to FIG. 7, the touch sensing layer TSU may include a touch sensor area TSA that senses a user's touch, and a touch peripheral area TOA disposed around the touch sensor area TSA. The touch sensor area TSA may be disposed in the display area DA of the display device 10, and the touch peripheral area TOA may be disposed in the non-display area NDA of the display device 10.

The touch sensor area TSA may include a plurality of touch electrodes SEN and a plurality of dummy electrodes DME. The plurality of touch electrodes SEN may form mutual capacitance or self-capacitance to sense a touch of an object or person. The plurality of touch electrodes SEN may include a plurality of driving electrodes TE and a plurality of sensing electrodes RE.

The driving electrodes TE may be arranged in the first direction DR1 and in the second direction DR2. The driving electrodes TE may be spaced apart from one another in the first direction DR1 and in the second direction DR2. The driving electrodes TE adjacent to one another in the second direction DR2 may be electrically connected through bridge electrodes CE.

The plurality of driving electrodes TE may be connected to first touch pads TP1 through driving lines TDL. The driving lines TDL may include lower driving lines TDLa and upper driving lines TDLb. For example, the driving electrodes TE disposed on the lower side of the touch sensor area TSA may be connected to the first touch pads TP1 through the lower driving lines TDLa, and the driving electrodes TE disposed on the upper side of the touch sensor area TSA may be connected to the first touch pads TP1 through the upper driving lines TDLb. The lower driving lines TDLa may be extended to the first touch pads TP1 beyond the lower side of the touch peripheral area TOA. The upper driving lines TDLb may be extended to the first touch pads TP1 via the upper side, the left side and the lower side of the touch peripheral area TOA. The first touch pads TP1 may be connected to the touch driver 400 through the circuit board 300.

Bridge electrodes CE may be bent at least once. Although the bridge electrodes CE may have the shape of angle brackets “<” or “>”, the shape of the bridge electrodes CE when viewed from the top is not limited thereto. The driving electrodes TE adjacent to one another in the second direction DR2 may be connected by the plurality of bridge electrodes CE. Even if one of the bridge electrodes CE is disconnected, the driving electrodes TE can be stably connected through the remaining bridge electrodes CE. The driving electrodes TE adjacent to each other may be connected by two bridge electrodes CE, but the number of bridge electrodes CE is not limited thereto.

The bridge electrodes CE may be disposed on a different layer from the plurality of driving electrodes TE and the plurality of sensing electrodes RE. The sensing electrodes RE adjacent to one another in the first direction DR1 may be electrically connected through connectors disposed in the same layer as the plurality of driving electrodes TE or the plurality of sensing electrodes RE. The driving electrodes TE adjacent to one another in the second direction DR2 may be electrically connected through the bridge electrodes CE disposed in a different layer from the plurality of driving electrodes TE or the plurality of sensing electrodes RE. Accordingly, even though the bridge electrodes CE overlap with the plurality of sensing electrodes RE in the z-axis direction, the plurality of driving electrodes TE and the plurality of sensing electrodes RE can be insulated from each other. Mutual capacitance may be formed between the driving electrodes TE and the sensing electrodes RE.

The sensing electrodes TE may be extended in the first direction DR1 and may be spaced apart from one another in the second direction DR2. The sensing electrodes RE may be arranged in the first direction DR1 and the second direction DR2, and the sensing electrodes RE adjacent to one another in the first direction DR1 may be electrically connected through connectors.

The plurality of sensing electrodes RE may be connected to second touch pads TP2 through sensing lines RL. For example, the sensing electrodes RE disposed on the right side of the touch sensor area TSA may be connected to the second touch pads TP2 through the sensing lines RL. The sensing lines RL may be extended to the second touch pads TP2 along the right side and the lower side of the touch peripheral area TOA. The second touch pads TP2 may be connected to the touch driver 400 through the circuit board 300.

Each of the plurality of dummy electrodes DME may be surrounded by the driving electrode TE or the sensing electrode RE. Each of the plurality of dummy electrodes DME may be spaced apart from and insulated from the driving electrode TE or the sensing electrode RE.

Accordingly, the dummy electrodes DME may be electrically floating.

The pad area PA, the first touch pad area TPA1 and the second touch pad area TPA2 may be disposed at the edge of the subsidiary area SBA. The pad area PA, the first touch pad area TPA1 and the second touch pad area TPA2 may be electrically connected to the circuit board 300 using a low-resistance, high-reliability material such as an anisotropic conductive film and a self-assembly anisotropic conductive paste (SAP).

The first touch pad area TPA1 may be disposed on one side of the pad area PA and may include the plurality of first touch pads TP1. The plurality of first touch pads TP1 may be electrically connected to the touch driver 400 disposed on the circuit board 300. The plurality of first touch pads TP1 may supply touch driving signals to the plurality of driving electrodes TE through the plurality of driving lines TL.

The second touch pad area TPA2 may be disposed on the opposite side of the pad area PA and may include the plurality of second touch pads TP2. The plurality of second touch pads TP2 may be electrically connected to the touch driver 400 disposed on the circuit board 300. The touch driver 400 may receive a touch sensing signal through the plurality of sensing lines RL connected to the plurality of second touch pads TP2, and may sense a change in the capacitance between the driving electrodes TE and the sensing electrodes RE.

According to an embodiment, the touch driver 400 may supply a touch driving signal to each of the plurality of driving electrodes TE and the plurality of sensing electrodes RE, and may receive a touch sensing signal from each of the plurality of driving electrodes TE and the plurality of sensing electrodes RE. The touch driver 400 may sense a change in the amount of charges in each of the plurality of driving electrodes TE and the plurality of sensing electrodes RE based on the touch sensing signal.

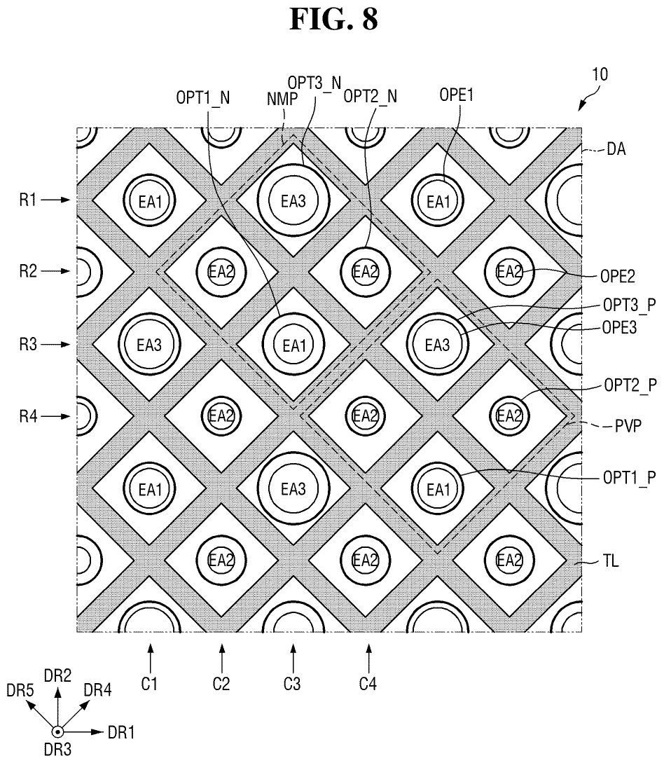

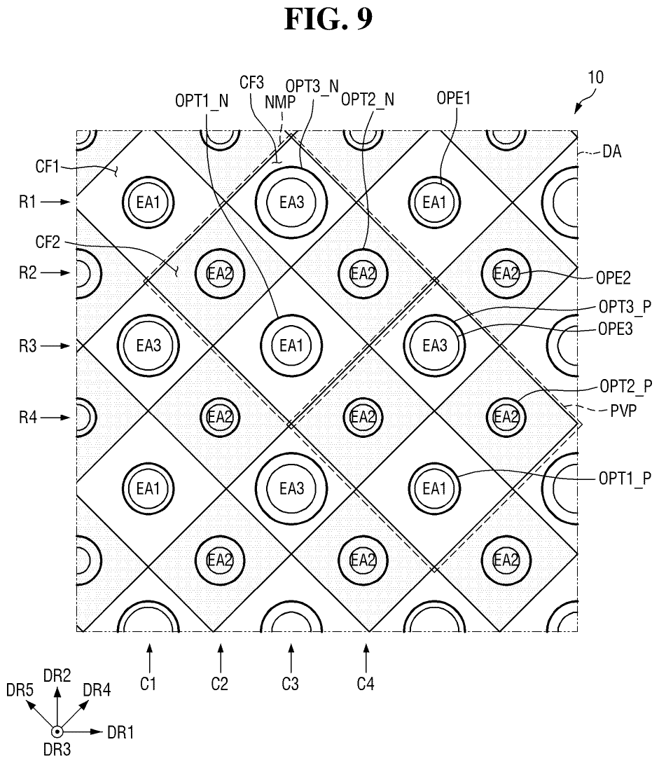

FIG. 8 is a plan view showing arrangements of emission areas EA1, EA2 and EA3 and touch electrodes TL in a display area DA of a display device 10 according to an embodiment. FIG. 9 is a plan view showing arrangement of color filters CF1, CF2 and CF3 in the display area DA of the display device 10 according to an embodiment.

Referring to FIGS. 8 and 9, the display device 10 may include the plurality of emission areas EA1, EA2 and EA3 arranged in the display area DA.

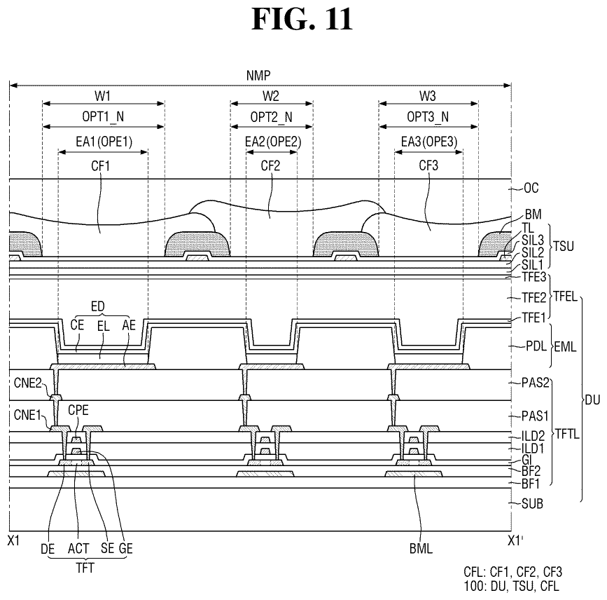

The emission areas EA1, EA2 and EA3 may include first emission areas EA1, second emission areas EA2 and third emission areas EA3 that emit lights of different colors. The first to third emission areas EA1, EA2 and EA3 may emit red, green and blue lights, respectively. The colors of lights emitted from the emission areas EA1, EA2 and EA3 may vary depending on the type of light-emitting elements ED (see FIG. 11) disposed in the emission material layer EML to be described later. According to an embodiment of the present disclosure, the first emission area EA1 may emit first light of red color, the second emission area EA2 may emit second light of green color, and the third emission area EA3 may emit third light of blue color. It should be understood, however, that the embodiments of the present disclosure are not limited thereto.

The emission areas EA1, EA2 and EA3 may be arranged in a PenTile™ matrix, for example, a diamond PenTile™ matrix. For example, the first emission area EA1 and the third emission area EA3 are spaced apart from each other in the first direction DR1, and may be arranged alternately in the first direction DR1 and the second direction DR2. With regard to the emission areas EA1, EA2 and EA3, the first emission area EA1 and the third emission area EA3 may be arranged alternately in the first direction DR1 in a first row R1 and a third row R3. In a first column C1 and a third column C3, the first emission area EA1 and the third emission area EA3 may be arranged alternately in the second direction DR2.

The second emission area EA2 may be spaced apart from another adjacent second emission area EA2 in the first direction DR1 and the second direction DR2, and may be spaced apart from an adjacent first emission area EA1 and a third emission area EA3 in a fourth direction DR4 or a fifth direction DR5. A plurality of second emission areas EA2 may be repeatedly arranged in the first direction DR1 and the second direction DR2, and the second emission area EA2 and the first emission area EA1, or the second emission area EA2 and the third emission area EA3 may be arranged alternately in the fourth direction DR4 or the fifth direction DR5. With regard to the arrangement of the emission areas EA1, EA2 and EA3, second emission areas EA2 may be arranged repeatedly in the first direction DR1 in a second row R2 and a fourth row R4, and second emission areas EA2 may arranged be repeatedly in the second direction DR2 in a second column C2 and a fourth column C4.

The first to third emission areas EA1, EA2 and EA3 may be defined by a plurality of openings OPE1, OPE2 and OPE3 formed in a pixel-defining layer PDL (see FIG. 11) of the emission material layer EML, which will be described later. For example, the first emission area EA1 may be defined by the first opening OPE1 of the pixel-defining layer, the second emission area EA2 may be defined by the second opening OPE2 of the pixel-defining layer, and the third emission area EA3 may be defined by the third opening OPE3 of the pixel-defining layer.

According to an embodiment of the present disclosure, the first to third emission areas EA1, EA2 and EA3 may have different areas or sizes. In the example shown in FIG. 8, the third emission area EA3 may be larger than the first emission area EA1 and the second emission area EA2, and the first emission area EA1 may be larger than the second emission area EA2. The sizes of the emission areas EA1, EA2 and EA3 may vary depending on the sizes of the opening OPE1, OPE2 and OPE3 formed in the pixel-defining layer. The intensity of lights emitted from the emission areas EA1, EA2 and EA3 may vary depending on the size of the emission areas EA1, EA2 and EA3. The colors of the images displayed on the display device 10 or the electronic device 1 can be controlled by adjusting the size of the emission areas EA1, EA2 and EA3. Although the third emission area EA3 is the largest in the example shown in FIG. 8, the present disclosure is not limited thereto. The size of the emission areas EA1, EA2 and EA3 may be adjusted as desired according to the colors of the images required by the display device 10 and the electronic device 1. In addition, the sizes of the emission areas EA1, EA2 and EA3 may be related to light efficiency, lifespan of the light-emitting elements ED, etc., and may have a trade-off relationship with reflection of external light. The sizes of the emission areas EA1, EA2 and EA3 may be adjusted by taking the above factors into account.

In the display device 10 having the arrangement of the emission areas EA1, EA2 and EA3 as shown in FIG. 8, one first emission area EA1, two second emission areas EA2 and one third emission area EA3 adjacent to one another may form a single pixel group. A single pixel group may represent black-and-white or grayscales by including the emission areas EA1, EA2 and EA3 emitting lights of different colors. It should be understood, however, that the present disclosure is not limited thereto. The combination of the emission areas EA1, EA2, and EA3 forming a single pixel group may be modified depending on the arrangement of the emission areas EA1, EA2 and EA3, and the colors of the lights emitted from them.

The display device 10 may include the plurality of color filters CF1, CF2 and CF3 disposed on the emission areas EA1, EA2 and EA3. The color filters CF1, CF2 and CF3 may be associated with the emission areas EA1, EA2 and EA3, respectively. For example, the color filters CF1, CF2 and CF3 may be disposed over a light-blocking layer BM including a plurality of holes OPT1_N, OPT1_P, OPT2_N, OPT2_P, OPT3_N and OPT3_P overlapping with the emission areas EA1, EA2 and EA3 or the openings OPE1, OPE2 and OPE3, respectively.

The holes OPT1_N, OPT1_P, OPT2_N, OPT2_P, OPT3_N and OPT3_P of the light-blocking layer BM (see FIG. 11) may be formed overlapping with the openings OPE1, OPE2 and OPE3, and may form light output areas where lights emitted from the emission areas EA1, EA2 and EA3 exit. The widths and sizes (or areas) of the holes OPT1_N, OPT1_P, OPT2_N, OPT2_P, OPT3_N and OPT3_P of the light-blocking layer BM (see FIG. 11) may be larger than the widths and sizes (or areas) of the emission areas EA1, EA2 and EA3.

The color filters CF1, CF2 and CF3 may have areas larger than the holes OPT1_N, OPT1_P, OPT2_N, OPT2_P, OPT3_N and OPT3_P of the light-blocking layer and the openings OPE1, OPE2 and OPE3. The color filters CF1, CF2 and CF3 may completely cover the light output areas formed by the holes OPT1_N, OPT1_P, OPT2_N, OPT2_P, OPT3_N and OPT3_P.

The color filters CF1, CF2 and CF3 include a first color filter CF1, a second color filter CF2 and a third color filter CF3 associated with the different emission areas EA1, EA2 and EA3, respectively. The color filters CF1, CF2 and CF3 may include a colorant such as a dye and pigment that absorbs lights in wavelength ranges other than light in a particular wavelength range, and may be disposed in association with the lights exiting from the emission areas EA1, EA2 and EA3. For example, the first color filter CF1 may be a red color filter that is disposed to overlap with the first emission area EA1 and transmits only first red light. The second color filter CF2 may be a green color filter that is disposed to overlap with the second emission area EA2 and transmits only green second light. The third color filter CF3 may be a blue color filter that is disposed to overlap with the third emission area EA3 and transmits only blue third light.

Similar to the arrangement of the emission areas EA1, EA2 and EA3, the color filters CF1, CF2 and CF3 may be arranged in the Pentile™ matrix, for example, the Diamond Pentile™ matrix. For example, the first color filter CF1 and the third color filter CF3 may be alternately arranged in the first direction DR1 and the second direction DR2. The color filters CF1, CF2 and CF3 may be arranged as follows: the first color filter CF1 and the third color filter CF3 may be alternately arranged in the first direction DR1 in the first row R1 and the third row R3. In the first column C1 and the third column C3, the first color filter CF1 and the third color filter CF3 may be arranged alternately in the second direction DR2.

The second color filter CF2 may be arranged in the first direction DR1 and the second direction DR2 with another adjacent second color filters CF2, and may be arranged in the fourth direction DR4 or the fifth direction DR5 with adjacent first color filter CF1 and third color filter CF3. A plurality of second color filters CF2 may be repeatedly arranged in the first direction DR1 and the second direction DR2, and the second color filter CF2 and the first color filter CF1, or the second color filter CF2 and the third color filter CF3 may be arranged alternately in the fourth direction DR4 or the fifth direction DR5. With regard to the arrangement of the color filters CF1, CF2 and CF3, second color filters CF2 may be arranged repeatedly in the first direction DR1 in the second row R2 and the fourth row R4, and second color filters CF2 may be arranged repeatedly in the second direction DR2 in the second column C2 and the fourth column C4.

According to an embodiment of the present disclosure, the color filters CF1, CF2 and CF3 may partially overlap with one another. Although adjacent ones of the color filters CF1, CF2 and CF3 meet one another in the example shown in FIG. 9, adjacent ones of the color filters CF1, CF2 and CF3 may partially overlap with one another at the borders where they meet each other, as will be described later in FIG. 11 and the like. FIG. 9 shows the arrangement of the color filters CF1, CF2 and CF3 when viewed from the top. It is to be understood that the edges of the underlying color filters CF1, CF2 and CF3 are hidden by the overlying color filters CF1, CF2 and CF3. The different color filters CF1, CF2 and CF3 may overlap one another on the light-blocking layer BM (see FIG. 11) that does not overlap with the emission areas EA1, EA2 and EA3, which will be described later.

In the display device 10, as the color filters CF1, CF2 and CF3 overlap one another, the intensity of reflected lights caused by external light can be reduced. Furthermore, the colors of reflected lights by external light can be controlled by adjusting the arrangement, shape and area of the color filters CF1, CF2 and CF3 when viewed from the top. Accordingly, the thickness of the display device 10 can be reduced because no separate optical film is disposed on the display panel 100. In addition, in case the display device 10 is a foldable device, folding stress can be mitigated.

Touch electrodes TL may be disposed between the emission areas EA1, EA2 and EA3. The touch electrodes TL may be extended in the fourth direction DR4 and the fifth direction DR5, and may not overlap with and may be spaced apart from the emission areas EA1, EA2 and EA3. The touch electrodes TL may overlap with the pixel-defining layer PDL (see FIG. 11) including openings OPE1, OPE2 and OPE3, and the light-blocking layer BM (see FIG. 11) including a plurality of holes OPT1_N, OPT1_P, OPT2_N, OPT2_P, OPT3_N and OPT3_P, which will be described later. Although the touch electrodes TL are briefly shown in FIG. 8, the touch electrodes TL may be either the touch driving electrodes TE or the sensing electrodes RE of FIG. 7.

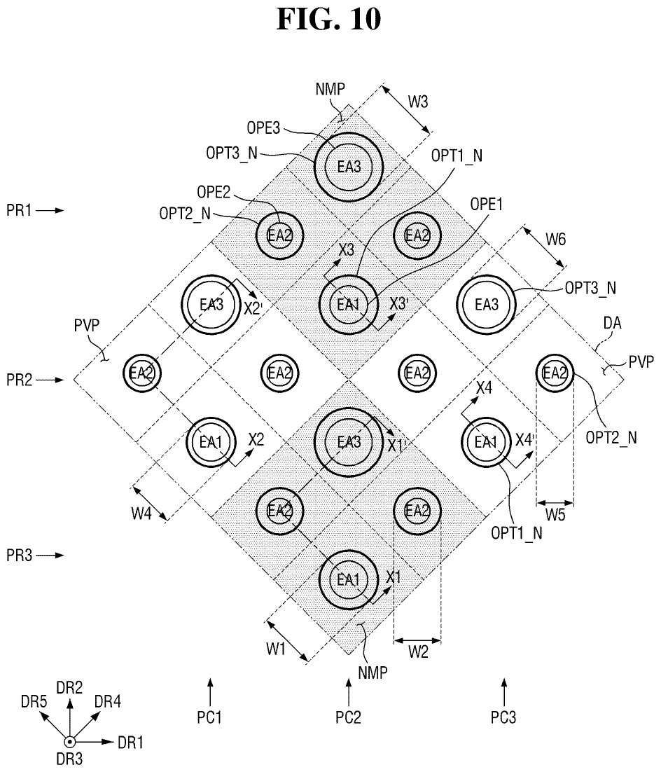

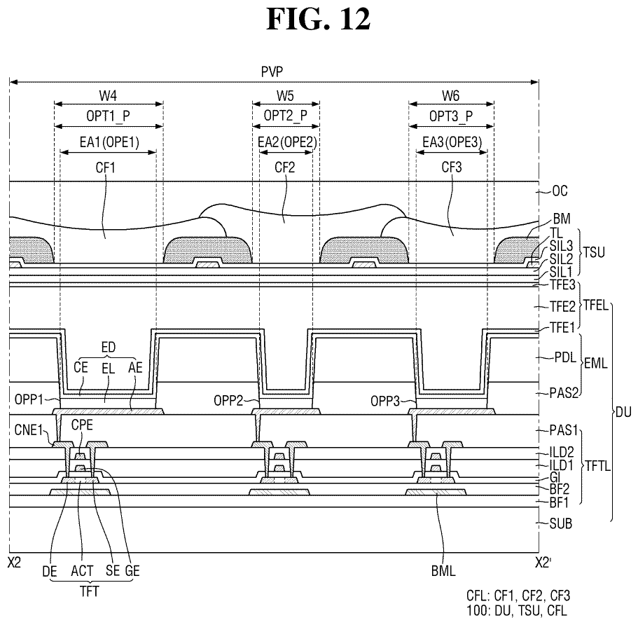

FIG. 10 is a plan view showing an arrangement of normal pixels NMP and privacy pixels PVP in a display area DA of a display device 10 according to an embodiment. FIG. 11 is a cross-sectional view taken along line X1-X1′ in FIG. 10. FIG. 12 is a cross-sectional view taken along line X2-X2′ of FIG. 10.

Referring to FIGS. 10 to 12 in conjunction with FIGS. 8 and 9, the display device 10 may include a normal mode and a privacy mode. The normal mode may be a driving mode in which the viewing angle is not controlled, and the privacy mode may be a driving mode in which the viewing angle is controlled. For example, the luminance ratio may be 20% or more on the side where the viewing angle relative to the front of the display surface is 45 degrees in the normal mode, while the luminance ratio may be 10% or less on the side where the viewing angle relative to the front side of the display surface is 45 degrees in the privacy mode. The numerical values of the viewing angles and luminance ratios are merely illustrative and are not limited to the above values.

The display area DA may include the normal pixels NMP and the privacy pixels PVP. The normal pixels NMP and the privacy pixels PVP may be distinguished from each other depending on whether or not they emit light in the privacy mode. For example, both the normal pixels NMP and the privacy pixels PVP may emit light in the normal mode, while the normal pixels NMP may not emit light and only the privacy pixels PVP may emit light in the privacy mode. As another example, only the normal pixels NMP may emit light and the privacy pixels PVP may not emit light in the normal mode.

The normal pixels NMP and the privacy pixels PVP may be alternately arranged in the fourth direction DR4 and the fifth direction DR5. For example, the normal pixels NMP may be arranged in the first direction DR1 in a first pixel row PR1 and a third pixel row PR3, and the privacy pixels PVP may be arranged in the first direction DR1 in a second pixel row PR2. The privacy pixels PVP may be arranged in the second direction DR2 in a first pixel column PC1 and a third pixel column PC3, and the normal pixels NMP may be arranged in the second direction DR2 in a second pixel column PC2.

Each of the normal pixels NMP and the privacy pixels PVP may include emission areas EA1, EA2 and EA3. As described above, one first emission area EA1, two second emission areas EA2 and one third emission area EA3 may form a single pixel group. The single pixel group may be a normal pixel NMP or a privacy pixel PVP. Specifically, each of the normal pixel NMP and the privacy pixel PVP may include one first emission area EA1, two second emission areas EA2 and one third emission area EA3. It should be understood, however, that the present disclosure is not limited thereto. The combination of the emission areas EA1, EA2, and EA3 forming the normal pixel NMP and the privacy pixel PVP may be modified depending on the arrangement of the emission areas EA1, EA2 and EA3, and the colors of the lights emitted from them.

Hereinafter, the cross-sectional structure of a normal pixel NMP will be described with reference to FIG. 11.

As shown in FIG. 11, the display panel 100 of the display device 10 may include a display layer DU, a touch sensing layer TSU, and a color filter layer CFL. The display layer DU may include a substrate SUB, a thin-film transistor layer TFTL, an emission material layer EML and an encapsulation layer TFEL. The display panel 100 may include the light-blocking layer BM disposed on the touch sensing layer TSU, and the color filters CF1, CF2 and CF3 of the color filter layer CFL may be disposed over the light-blocking layer BM.

The substrate SUB may be a base substrate or a base member. The substrate SUB may be a flexible substrate that can be bent, folded, or rolled. For example, the substrate SUB may include, but is not limited to, a polymer resin such as polyimide (PI). For another example, the substrate SUB may include a glass material or a metal material.

The thin-film transistor layer TFTL may include a first buffer layer BF1, a bottom metal layer BML, a second buffer layer BF2, a thin-film transistor TFT, a gate insulator GI, a first interlayer dielectric layer ILD1, a capacitor electrode CPE, a second interlayer dielectric layer ILD2, a first connection electrode CNE1, a first passivation layer PAS1, a second connection electrode CNE2 and a second passivation layer PAS2.

The first buffer layer BF1 may be disposed on the substrate SUB. The first buffer layer BF1 may include an inorganic film capable of preventing permeation of air or moisture. For example, the first buffer layer BF1 may include a plurality of inorganic films stacked on one another alternately.

The bottom metal layer BML may be disposed on the first buffer layer BF1. For example, the bottom metal layer BML may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The second buffer layer BF2 may cover the first buffer layer BF1 and the bottom metal layer BML. The second buffer layer BF2 may include an inorganic film capable of preventing permeation of air or moisture. For example, the second buffer layer BF2 may include a plurality of inorganic films stacked on one another alternately.

The thin-film transistor TFT may be disposed on the second buffer layer BF2 and may form a pixel circuit of each of a plurality of pixels. For example, the thin-film transistor TFT may be a driving transistor or a switching transistor of the pixel circuit. The thin-film transistor TFT may include a semiconductor layer ACT, a source electrode SE, a drain electrode DE and a gate electrode GE.

The semiconductor layer ACT may be disposed on the second buffer layer BF2. The semiconductor layer ACT may overlap the bottom metal layer BML and the gate electrode GE in the thickness direction and may be insulated from the gate electrode GE by the gate insulator GI. The material of a part of the semiconductor layer ACT may be made conductive to form the source electrode SE and the drain electrode DE.

The gate electrode GE may be disposed on the gate insulator GI. The gate electrode GE may overlap the semiconductor layer ACT with the gate insulating layer GI interposed therebetween.

The gate insulator GI may be disposed on the semiconductor layer ACT. For example, the gate insulator GI may cover the semiconductor layer ACT and the second buffer layer BF2, and may insulate the semiconductor layer ACT from the gate electrode GE. The gate insulator GI may include a contact hole through which the first connection electrode CNE1 passes.

The first interlayer dielectric layer ILD1 may cover the gate electrode GE and the gate insulator GI. The first interlayer dielectric layer ILD1 may include a contact hole through which the first connection electrode CNE1 passes. The contact holes of the first interlayer dielectric layer ILD1 may be connected to the contact holes of the gate insulator GI and the contact holes of the second interlayer dielectric layer ILD2.

The capacitor electrode CPE may be disposed on the first interlayer dielectric layer ILD1. The capacitor electrode CPE may overlap with the gate electrode GE in the thickness direction. The capacitor electrode CPE and the gate electrode GE may form a capacitance.

The second interlayer dielectric layer ILD2 may cover the capacitor electrode CPE and the first interlayer dielectric layer ILD1. The second interlayer dielectric layer ILD2 may include a contact hole through which the first connection electrode CNE1 passes. The contact hole of the second interlayer dielectric layer ILD2 may be connected to the contact hole of the first interlayer dielectric layer ILD1 and the contact hole of the gate insulator GI.

The first connection electrode CNE1 may be disposed on the second interlayer dielectric layer ILD2. The first connection electrode CNE1 may electrically connect the drain electrode DE of the thin-film transistor TFT with the second connection electrode CNE2. The first connection electrode CNE1 may be inserted into a contact hole formed in the second interlayer dielectric layer ILD2, the first interlayer dielectric layer ILD1, and the gate insulator GI to be in contact with the drain electrode DE of the thin-film transistor TFT.

The first passivation layer PAS1 may cover the first connection electrode CNE1 and the second interlayer dielectric layer ILD2. The first passivation layer PAS1 can protect the thin-film transistor TFT. The first passivation layer PAS1 may include a contact hole through which the second connection electrode CNE2 passes.

The second connection electrode CNE2 may be disposed on the first passivation layer PAS1. The second connection electrode CNE2 may electrically connect the first connection electrode CNE1 with a pixel electrode AE of a light-emitting element ED. The second connection electrode CNE2 may be inserted into a contact hole formed in the first passivation layer PAS1 to be in contact with the first connection electrode CNE1.

The second passivation layer PAS2 may cover the second connection electrode CNE2 and the first passivation layer PAS1. The second passivation PAS2 may include a contact hole through which the pixel electrode AE of the light-emitting diode ED passes.

The emission material layer EML may be disposed on the thin-film transistor layer TFTL. The emission material layer EML may include the light-emitting element ED and a pixel-defining layer PDL. The light-emitting element ED, sometimes called the light-emitting diode ED, may include the anode electrode AE, an emissive layer EL, and a common electrode CE.

The pixel electrode AE may be disposed on the second passivation layer PAS2. The pixel electrode AE may be disposed overlapping with one of openings OPE1, OPE2 and OPE3 of the pixel-defining layer PDL. The pixel electrode AE may be electrically connected to the drain electrode DE of the thin-film transistor TFT through the first and second connection electrodes CNE1 and CNE2.

The emissive layer EL may be disposed on the pixel electrode AE. The emissive layer EL may be disposed in the openings OPE1, OPE2 and OPE3 of the pixel-defining layer PDL. For example, the emissive layer EL may be, but is not limited to, an organic emissive layer made of an organic material. If the emissive layer EL is an organic emissive layer, when the thin-film transistor applies a predetermined voltage to the pixel electrode AE of the light-emitting diode ED and the common electrode CE of the light-emitting diode ED receives a common voltage or cathode voltage, the holes and electrons may move to the emissive layer EL through the hole transporting layer and the electron transporting layer, respectively, and they combine in the emissive layer EL to emit light.

The common electrode CE may be disposed on the emissive layer EL. For example, the common electrode CE may be implemented as an electrode common to all pixels, instead of being disposed as a separated electrode for each of the pixels. The common electrode CE may be disposed on the emissive layer EL in the first to third emission areas EA1, EA2 and EA3, and may be disposed on the pixel-defining layer PDL in the other areas than the first to third emission areas EA1, EA2 and EA3.

The common electrode CE may receive a common voltage or a low-level voltage. When the pixel electrode AE receives the voltage equal to the data voltage and the common electrode CAT receives the low-level voltage, a potential difference is formed between the pixel electrode AE and the common electrode CE, so that the emissive layer EL can emit light.

The pixel-defining layer PDL may include the plurality of openings OPE1, OPE2 and OPE3, and may be disposed on the second passivation layer PAS2 and a part of the pixel electrode AE. The pixel-defining layer PDL may include the first opening OPE1, the second opening OPE2 and the third opening OPE3, and each of the openings OPE1, OPE2 and OPE3 extends to a part of the pixel electrode AE. As described above, the openings OPE1, OPE2 and OPE3 of the pixel-defining layer PDL may define the first to third emission areas EA1, EA2 and EA3, respectively, which may have different areas or sizes. The pixel-defining layer PDL may separate and insulate the pixel electrode AE of one of the plurality of light-emitting diodes ED from the pixel electrode of another one of the light-emitting diodes ED. The pixel-defining layer PDL may include a light-absorbing material to prevent light reflection. For example, the pixel-defining layer PDL may include a polyimide (PI)-based binder, and pigments in which red, green and blue are mixed. In an embodiment, the pixel-defining layer PDL may include a cardo-based binder resin and a mixture of lactam black pigment and blue pigment. In an embodiment, the pixel-defining layer PDL may include carbon black.

The encapsulation layer TFEL may be disposed on the common electrode CE to cover the light-emitting elements ED. The encapsulation layer TFEL may include at least one inorganic layer to prevent permeation of oxygen or moisture into the emission material layer EML. The encapsulation layer TFEL may include at least one organic layer to protect the emission material layer EML from foreign substances such as dust.

According to an embodiment of the present disclosure, the encapsulation layer TFEL may include a first encapsulation layer TFE1, a second encapsulation layer TFE2 and a third encapsulation layer TFE3. The first encapsulation layer TFE1 and the third encapsulation layer TFE3 may be inorganic encapsulation layers, and the second encapsulation layer TFE2 disposed therebetween may be an organic encapsulation layer.

Each of the first encapsulation layer TFE1 and the third encapsulation layer TFE3 may include one or more inorganic insulating materials. The inorganic insulating material may include aluminum oxide, titanium oxide, tantalum oxide, hafnium oxide, zinc oxide, silicon oxide, silicon nitride, and/or silicon oxynitride.

The second encapsulation layer TFE2 may include a polymer-based material. The polymer-based material may include an acrylic resin, an epoxy resin, polyimide, polyethylene, etc. For example, the second encapsulation layer TFE2 may include an acrylic resin, e.g., polymethyl methacrylate, polyacrylic acid, etc. The second encapsulation layer TFE2 may be formed by curing a monomer or by applying a polymer.

The touch sensing layer TSU may be disposed on the encapsulation layer TFEL. The touch sensing layer TSU may include a first touch insulating layer SIL1, a second touch insulating layer SIL2, touch electrodes TL, and a third touch insulating layer SIL3.

The first touch insulating layer SIL1 may be disposed on the encapsulation layer TFEL. The first touch insulating layer SIL1 may have insulating properties and optical features. The first touch insulating layer SIL1 may include at least one inorganic film. Optionally, the first touch insulating layer SIL1 may be eliminated.

The second touch insulating layer SIL2 may cover the first touch insulating layer SILL. Although not shown in the drawings, a touch electrode of another layer may be further disposed on the first touch insulating layer SIL1, and the second touch insulating layer SIL2 may cover such a touch electrode. The second touch insulating layer SIL2 may have insulating properties and optical features. For example, the second touch insulating layer SIL2 may be an inorganic layer including at least one selected from the group consisting of: a silicon nitride layer, a silicon oxynitride layer, a silicon oxide layer, a titanium oxide layer and an aluminum oxide layer.

Some of the touch electrodes TE may be disposed on the second touch insulating layer SIL2. The touch electrodes TL may not overlap with the first to third emission areas EA1, EA2 and EA3. Each of the touch electrodes TL may be made up of a single layer of molybdenum (Mo), titanium (Ti), copper (Cu), aluminum (Al), or indium tin oxide (ITO), or may be made up of a stack structure of aluminum and titanium (Ti/Al/Ti), a stack structure of aluminum and ITO (ITO/Al/ITO), an APC alloy and a stack structure of an APC alloy and ITO (ITO/APC/ITO).

The third touch insulating layer SIL3 may cover the touch electrodes TL and the second touch insulating layer SIL2. The third touch insulating layer SIL3 may have insulating properties and optical features. The third touch insulating layer SIL3 may be made of one of the above-listed materials as the material of the second touch insulating layer SIL2.

The light-blocking layer BM may be disposed on the third touch insulating layer SIL3 of the touch sensing layer TSU. The light-blocking layer BM may be disposed to cover a conductive line of the touch electrodes TL and may include a plurality of holes OPT1_N, OPT2_N and OPT3_N disposed in the emission areas EA1, EA2 and EA3, respectively. For example, the first hole OPT1_N may be overlapping with the first emission area EA1 or the first opening OPE1, the second hole OPT2_N may be overlapping with the second emission area EA2 or the second opening OPE2, and the third hole OPT3_N may be overlapping with the third emission area EA3 or the third opening OPE3. The areas or sizes of the holes OPT1_N, OPT2_N and OPT3_N may be larger than the areas or sizes of the openings OPE1, OPE2 and OPE3 of the pixel-defining layer PDL. As the holes OPT1_N, OPT2_N and OPT3_N of the light-blocking layer BM are larger than the openings OPE1, OPE2 and OPE3 of the pixel-defining layer PDL, the lights output from the emission areas EA1, EA2 and EA3 may be seen by a user not only from the front but also from the sides of the display device 10.

The light-blocking layer BM may include a light-absorbing material. For example, the light-blocking layer BM may include an inorganic black pigment or an organic black pigment. The inorganic black pigment may be, but is not limited to, carbon black, and the organic black pigment may include, but is not limited to, at least one of lactam black, perylene black, and aniline black. The light-blocking layer BM can prevent visible light from penetrating and mixing colors between the first to third emission areas EA1, EA2 and EA3 to improve the color gamut of the display device 10.

The color filters CF1, CF2 and CF3 of the color filter layer CFL may be disposed on the light-blocking layer BM. Different color filters CF1, CF2 and CF3 may be disposed overlapping with different emission areas EA1, EA2 and EA3 or openings OPE1, OPE2 and OPE3, and the holes OPT1_N, OPT2_N and OPT3_N of the light-blocking layer BM, respectively. For example, the first color filter CF1 may be overlapping with the first emission area EA1, the second color filter CF2 may be overlapping with the second emission area EA2, and the third color filter CF3 may be overlapping with the third emission area EA3. The first color filter CF1 may be disposed in the first hole OPT1_N of the light-blocking layer BM, the second color filter CF2 may be disposed in the second hole OPT2_N of the light-blocking layer BM, and the third color filter CF3 may be disposed in the third hole OPT3_N of the light-blocking layer BM. The color filters CF1, CF2 and CF3 may have a larger area than the holes OPT1_N, OPT2_N and OPT3_N of the light-blocking layer BM when viewed from the top, and some of them may be disposed directly on the light-blocking layer BM.

The color filters CF1, CF2 and CF3 of the display device 10 may be arranged to overlap with other adjacent color filters CF1, CF2 and CF3 on the light-blocking layer BM. The color filters CF1, CF2 and CF3 disposed on the light-blocking layer BM may be arranged such that two adjacent ones of the color filters CF1, CF2 and CF3 completely cover the light-blocking layer BM. Two adjacent ones of the color filters CF1, CF2 and CF3 may be arranged to partially overlap each other on the light-blocking layer BM. As these color filters CF1, CF2 and CF3 overlap one another, reflection of external light can be further reduced in addition to the light-blocking layer BM.

A planarization layer OC may be disposed on the color filters CF1, CF2 and CF3 to provide flat upper ends of the color filters CF1, CF2 and CF3. The planarization layer OC may be a colorless light-transmitting layer having no color in the visible light range. For example, the planarization layer OC may include a colorless light-transmitting organic material such as an acryl-based resin.

Hereinafter, the cross-sectional structure of a privacy pixel PVP will be described with reference to FIG. 12. In the following description, the same configuration as the cross-sectional structure of the normal pixel NMP described above with reference to FIG. 11 will not be described or briefly described. Descriptions will focus on differences.

In a privacy pixel PVP, a second passivation layer PAS2 may include a plurality of connection openings OPP1, OPP2 and OPP3 overlapping with a plurality of openings OPE1, OPE2 and OPE3 of a pixel-defining layer PDL or emission areas EA1, EA2 and EA3. For example, the first connection opening OPP1 may be overlapping with the first emission area EA1 or the first opening OPE1, the second connection opening OPP2 may be overlapping with the second emission area EA2 or the second opening OPE2, and the third connection opening OPP3 may be overlapping with the third emission area EA3 or the third opening OPE3.

In the privacy pixel PVP, the second passivation layer PAS2 may be included in an emission material layer EML. The connection openings OPP1, OPP2 and OPP3 of the second passivation layer PAS2 may be connected to the plurality of openings OPE1, OPE2 and OPE3 of the pixel-defining layer PDL to form single openings, respectively. For example, the first connection opening OPP1 may be connected to the first opening OPE1 to form a single opening, the second connection opening OPP2 may be connected to the second opening OPE2 to form a single opening, and the third connection opening OPP3 may be connected to the third opening OPE3 to form a single opening.

The openings formed by connecting the connection openings OPP1, OPP2 and OPP3 of the second passivation layer PAS2 with the plurality of openings OPE1, OPE2 and OPE3 of the pixel-defining layer PDL may extend to and expose parts of the pixel electrodes AE.

In the privacy pixel PVP, the emission material layer EML may be disposed on the first passivation layer PAS1. The pixel electrode AE may be disposed on the first passivation layer PAS1. The pixel electrode AE may overlap with one of the openings OPE1, OPE2 and OPE3 of the pixel-defining layer PDL, and may overlap with one of the connection openings OPP1, OPP2 and OPP3 of the second passivation layer PAS2.

According to an embodiment of the present disclosure, the second connection electrode CNE2 may be eliminated in the privacy pixel PVP. The pixel electrode AE may be electrically connected to the drain electrode DE of the thin-film transistor TFT through the first connection electrode CNE1.

The emissive layer EL may be disposed in each of the openings formed by connecting the connection openings OPP1, OPP2 and OPP3 of the second passivation layer PAS2 with the openings OPE1, OPE2 and OPE3 of the pixel-defining layer PDL. Although the upper surface of the emissive layer EL is lower than the upper surface of the second passivation layer PAS2 in the drawings, the present disclosure is not limited thereto. For example, the upper surface of the emissive layer EL may be higher than the upper surface of the second passivation layer PAS2, and the upper surface of the emissive layer EL may be located in each of the openings OPE1, OPE2 and OPE3 of the pixel-defining layer PDL.

The common electrode CE may cover the inner surfaces of the openings OPEL, OPE2 and OPE3 of the pixel-defining layer PDL and the inner surfaces of the connection openings OPP1, OPP2 and OPP3 of the second passivation layer PAS2.

At least a portion of the first encapsulation layer TFE1 and at least a portion of the second encapsulation layer TFE2 may be disposed in the openings formed by connecting the connection openings OPP1, OPP2 and OPP3 of the second passivation layer PAS2 with the openings OPEL, OPE2 and OPE3 of the pixel-defining layer PDL.

In the privacy pixel PVP, the light-blocking layer BM may include a plurality of holes OPT1_P, OPT2_P and OPT3_P overlapping with the emission areas EA1, EA2 and EA3, respectively. For example, the fourth hole OPT1_P may be overlapping with the first emission area EA1 or the first opening OPEL1, the fifth hole OPT2_P may be overlapping with the second emission area EA2 or the second opening OPE2, and the sixth hole OPT3_P may be overlapping with the third emission area EA3 or the third opening OPE3. The areas or sizes of the holes OPT1_P, OPT2_P and OPT3_P may be larger than the areas or sizes of the openings OPEL, OPE2 and OPE3 of the pixel-defining layer PDL. As the holes OPT1_P, OPT2_P and OPT3_P of the light-blocking layer BM are larger than the openings OPEL, OPE2 and OPE3 of the pixel-defining layer PDL, the lights output from the emission areas EA1, EA2 and EA3 may be seen by a user not only from the front but also from the sides of the display device 10.

According to some embodiments, the widths of the holes OPT1_P, OPT2_P and OPT3_P of the light-blocking layer BM in the privacy pixel PVP may be smaller than the widths of the holes OPT1_N, OPT2_N and OPT3_N of the light-blocking layer BM in the normal pixel NMP. For example, the width W4 of the fourth hole OPT1_P may be smaller than the width W1 of the first hole OPT1_N, the width W5 of the fifth hole OPT2_P may be smaller than the width W2 of the second hole OPT2_N, and the width W6 of the sixth hole OPT3_P may be smaller than the width W3 of the third hole OPT3_N.

In the display device 10 according to this embodiment, as the widths of the holes OPT1_P, OPT2_P and OPT3_P of the light-blocking layer BM in the privacy pixel PVP is smaller than the widths of the holes OPT1_N, OPT2_N and OPT3_N of the light-blocking layer BM in the normal pixel NMP, the luminance of light that exits at a certain angle or higher on the sides may be reduced, and thus the viewing angle of the display device 10 may be reduced.

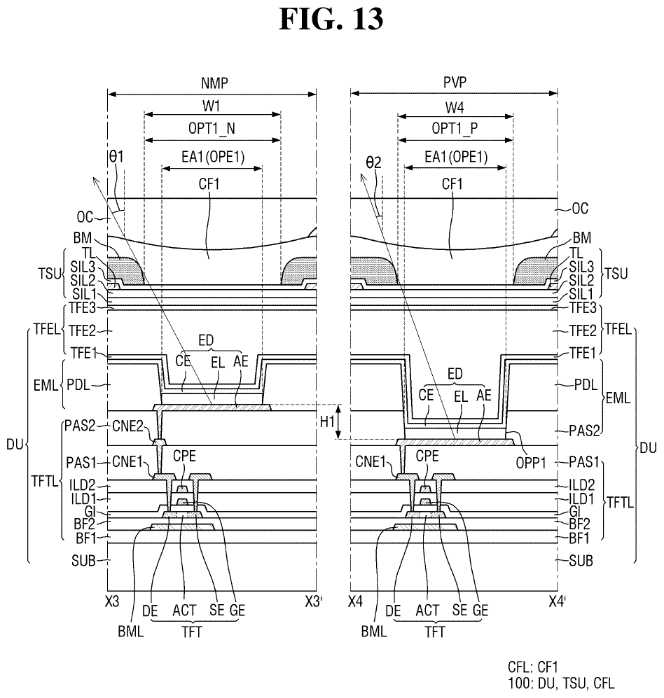

Incidentally, in the display device 10 according to this embodiment, by adjusting the distance between the light-blocking layer BM and the emissive layer EL (e.g., the distance in the third direction DR3), it is possible to further reduce the viewing angle of the display device 10. Accordingly, even in the high-resolution display device 10, the viewing angle can be adjusted regardless of the widths of the holes OPT1_P, OPT2_P and OPT3_P in the light-blocking layer BM. This will be described below with reference to FIG. 13.

FIG. 13 is a cross-sectional view, taken along lines X3-X3′ and X4-X4′ in FIG. 10.

Referring to FIG. 13 in conjunction with FIGS. 10 to 12, as the display device 10 includes the first connection opening OPP1 of the second protective layer PAS2, the emissive layer EL in the privacy pixel PVP may be located lower than the emissive layer EL in the normal pixel NMP. For example, the emissive layer EL in the privacy pixel PVP may be located lower than the emissive layer EL in the normal pixel NMP by a first height H1.

The distance between the emissive layer EL and the light-blocking layer BM in the privacy pixel PVP may be greater than the distance between the emissive layer EL and the light-blocking layer BM in the normal pixel NMP. The maximum viewing angle of light emitted from the emissive layer EL of the normal pixel NMP may be a first angle θ1. The maximum viewing angle of light emitted from the emissive layer EL of the privacy pixel PVP may be a second angle θ2. The second angle θ2 may be smaller than the first angle θ1.

In the display device 10 according to this embodiment, the light-emitting element ED in the privacy pixel PVP is located lower than the light-emitting element ED in the normal pixel NMP, so that driving modes with different viewing angles can be achieved using one light-blocking layer BM. Accordingly, no separate louver or no additional second light-blocking layer is required on the light-blocking layer BM to control the viewing angle, and thus the process efficiency can be improved and the thickness of the display device 10 can be reduced.

Hereinafter, display devices according to other exemplary embodiments of the present disclosure will be described. In the following description, the same or similar elements will be denoted by the same or similar reference numerals, and redundant descriptions will be omitted or briefly described.

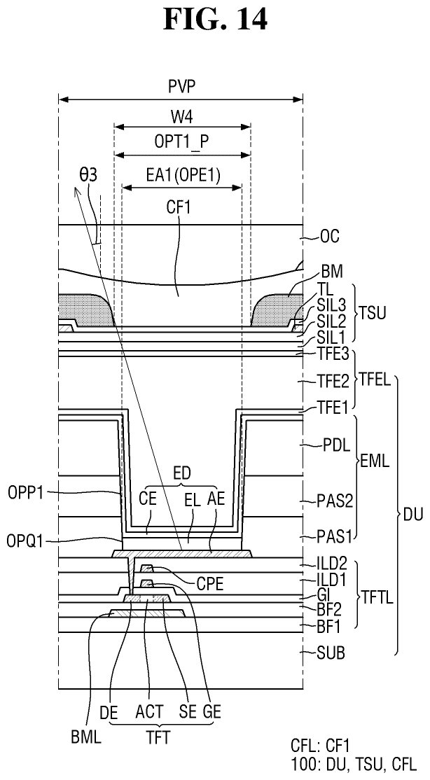

FIG. 14 is a cross-sectional view showing an emission area EA1 in a privacy pixel PVP of a display device 10 according to an embodiment. Although FIG. 14 shows a first emission area EA1 as an example, it is to be understood that the same technical idea may be applied to a second emission area EA2 and a third emission area EA3.

The display device 10 according to this embodiment of FIG. 14 is different from the display device 10 according to the embodiment of FIG. 12 and the like in that a first passivation layer PAS1 includes a fourth connection opening OPQ1.

More specifically, in the privacy pixel PVP, the first passivation layer PAS1 may include the fourth connection opening OPQ1 overlapping with a first opening OPE1 of a pixel-defining layer PDL and a first connection opening OPP1 of a second protective layer PAS2.

In the privacy pixel PVP, the first passivation layer PAS1 may be included in an emission material layer EML. The fourth connection opening OPQ1 of the first passivation layer PAS1 may be connected to the first opening OPE1 of the pixel-defining layer PDL and the first connection opening OPP1 of the second passivation layer PAS2 to form a single opening.

The opening formed by connecting the fourth connection opening OPQ1 of the first passivation layer PAS1 with the first connection opening OPP1 of the second passivation layer PAS2 and the first opening OPE1 of the pixel-defining layer PDL may extend to and expose a part of a pixel electrode AE.

In the privacy pixel PVP, the emission material layer EML may be disposed on a second interlayer dielectric layer ILD2. The pixel electrode AE may be disposed on the first interlayer dielectric layer ILD2. The pixel electrode AE may overlap with the first opening OPE1 of the pixel-defining layer PDL, may overlap with the first connection opening OPP1 of the second passivation layer PAS2, and may overlap with the fourth connection opening OPQ1 of the first passivation layer PAS1.

According to an embodiment of the present disclosure, a first connection electrode CNE1 may be eliminated in the privacy pixel PVP. The pixel electrode AE may be electrically connected directly to a drain electrode DE of a thin-film transistor TFT.

The emissive layer EL may be disposed in the opening formed by connecting the fourth connection opening OPQ1 of the first passivation layer PAS1 with the first connection opening OPP1 of the second passivation layer PAS2 and the first opening OPE1 of the pixel-defining layer PDL. Although the upper surface of the emissive layer EL is lower than the upper surface of the first passivation layer PAS1 in the drawings, the present disclosure is not limited thereto. For example, the upper surface of the emissive layer EL may be higher than the upper surface of the first passivation layer PAS1, and the upper surface of the emissive layer EL may be located in the first connection opening OPP1 of the second passivation layer PAS2 or may be located in the first opening OPE1 of the pixel-defining layer PDL.

A common electrode CE may cover the inner surface of the first opening OPE1 of the pixel-defining layer PDL, the inner surface of the first connection opening OPP1 of the second passivation layer PAS2, and the inner surface of the fourth connection opening OPQ1 of the first passivation layer PAS1.

At least a portion of the first encapsulation layer TFE1 and at least a portion of the second encapsulation layer TFE2 may be disposed in the opening formed by connecting the fourth connection opening OPQ1 of the first passivation layer PAS1 with the first connection opening OPP1 of the second passivation layer PAS2 and the first opening OPE1 of the pixel-defining layer PDL.

In the display device 10 according to this embodiment, the difference between the distance from the emissive layer EL to the light-blocking layer BM in the privacy pixel PVP and the distance from the emissive layer EL to the light-blocking layer BM in the normal pixel NMP may be larger than that in the display device 10 described above with reference to FIG. 13 and the like. In the display device 10 according to this embodiment, the maximum viewing angle of light emitted from the emissive layer EL in the privacy pixel PVP may be a third angle θ3. The third angle θ3 may be smaller than the second angle θ2 (see FIG. 13). Accordingly, the viewing angle of the display device 10 can be further reduced.

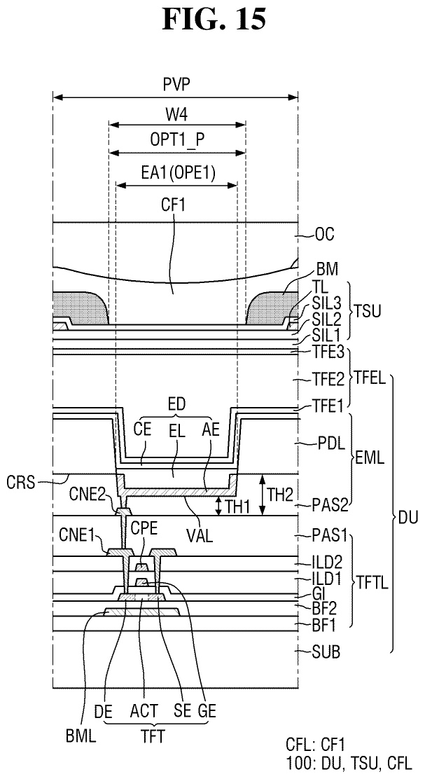

FIG. 15 is a cross-sectional view showing an emission area EA1 of a privacy pixel PVP of a display device 10 according to an embodiment. Although FIG. 15 shows a first emission area EA1 as an example, it is to be understood that the same technical idea may be applied to a second emission area EA2 and a third emission area EA3.

The display device 10 according to the embodiment of FIG. 15 is different from the display device 10 according to the embodiment of FIG. 12 and the like in that a second passivation layer PAS2 includes a crest CRS and a valley VAL.

More specifically, in the privacy pixel PVP, the second passivation layer PAS2 may include a valley VAL overlapping with a first opening OPE1 of the pixel-defining layer PDL and a crest CRS placed on one side of the valley VAL. A thickness TH1 of the valley VAL may be smaller than a thickness TH2 of the crest CRS. The upper surface of the valley VAL may be lower than the upper surface of the crest CRS.

The crest CRS and the valley VAL of the second passivation layer PAS2 may be formed using a half-tone mask. For example, the crest CRS and the valley VAL having different thicknesses may be formed by exposing a material layer of the second passivation layer PAS2 to light and etching it using a halftone mask with different transmittance for different regions. By adjusting the transmittance of the halftone mask, the thicknesses of the crest CRS and valley VAL may be adjusted.

In the privacy pixel PVP, the second passivation layer PAS2 may be included in an emission material layer EML. The valley VAL of the second passivation layer PAS2 may be connected to the first opening OPE1 of the pixel-defining layer PDL to form a recess part.

The recess part formed by connecting the valley VAL of the second passivation layer PAS2 with the first opening OPE1 of the pixel-defining layer PDL may extend to and expose a portion of the pixel electrode AE.

In the privacy pixel PVP, the emission material layer EML may be disposed on the second passivation layer PAS2. The pixel electrode AE may be disposed on the valley VAL of the second passivation layer PAS2. The pixel electrode AE may overlap with the first opening OPE1 of the pixel-defining layer PDL and may overlap with the valley VAL of the second passivation layer PAS2. According to the embodiment of the present disclosure, the pixel electrode AE of the privacy pixel PVP may be electrically connected to the drain electrode DE of the thin-film transistor TFT through the first and second connection electrodes CNE1 and CNE2.

The emissive layer EL may be disposed in the recess part formed by connecting the valley VAL of the second passivation layer PAS2 with the first opening OPE1 of the pixel-defining layer PDL. Although the upper surface of the emissive layer EL is higher than the upper surface of the crest CRS of the second passivation layer PAS2 in the drawings, the present disclosure is not limited thereto. For example, the upper surface of the emissive layer EL may be located lower than the upper surface of the second passivation layer PAS2.

The common electrode CE may cover the inner surface of the first opening OPEL of the pixel-defining layer PDL. Although not shown in the drawings, in some embodiments, the common electrode CE may cover the side surfaces of the second passivation layer PAS2 located between the crest CRS and the valley VAL.

At least a portion of the first encapsulation layer TFE1 and at least a portion of the second encapsulation layer TFE2 may be disposed in the recess part formed by connecting the valley VAL of the second passivation layer PAS2 with the first opening OPEL of the pixel-defining layer PDL.

The display device 10 according to this embodiment may adjust the distance between the emissive layer EL and the light-blocking layer BM by adjusting the thicknesses of the crest CRS and the valley VAL of the second passivation layer PAS2 using a halftone mask. Accordingly, the viewing angle of the display device 10 can be adjusted as desired.

In some embodiments, although not shown in the drawing, the second passivation layer PAS2 may include the first connection opening OPP1 (see FIG. 14), and the first passivation layer PAS1 may include a valley VAL. In this instance, the first opening OPEL of the pixel-defining layer PDL, the first connection opening OPP1 of the second passivation layer PAS2 (see FIG. 14), and the valley VAL of the first passivation layer PAS1 may form a single recess part.

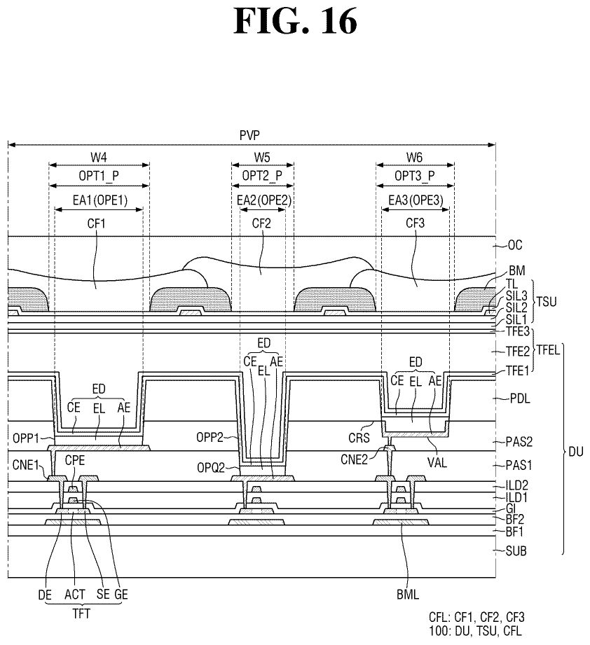

FIG. 16 is a cross-sectional view showing a privacy pixel PVP in a display device 10 according to an embodiment of the present disclosure.

The display device 10 according to the embodiment of FIG. 16 is different from the display device 10 according to the embodiment of FIG. 12 and the like in that an emissive layer EL has different levels in different emission areas EA1, EA2 and EA3.

More specifically, the emissive layer EL of the first emission area EA1 according to this embodiment may be located at the same level as the emissive layer EL described above with reference to FIGS. 12 and 13, etc. The emissive layer EL of the second emission area EA2 according to this embodiment may be located at the same level as the emissive layer EL described above with reference to FIG. 14. The emissive layer EL of the third emission area EA3 according to this embodiment may be located at the same level as the emissive layer EL described above with reference to FIG. 15.

The second passivation layer PAS2 of the first emission area EA1 may include a first connection opening OPP1. The second passivation layer PAS2 of the second emission area EA2 may include a second connection opening OPP2, and the first passivation layer PAS1 of the second emission area EA2 may include a fifth connection opening OPQ2. The second passivation layer PAS2 of the third emission area EA3 may include a valley VAL and a crest CRS.

Although the emissive layer EL of the first emission area EA1 is located at the same level as that of the embodiment of FIGS. 12 and 13, the emissive layer EL of the second emission area EA2 is located at the same level as that of the embodiment of FIG. 14, and the emissive layer EL of the third emission area EA3 is located at the same level as that of the embodiment of FIG. 15 in the drawing, the present disclosure is not limited thereto. As an example, the emissive layer EL in all of the emission areas EA1, EA2 and EA3 may be located at the same level as the emissive layer EL of one of the embodiment of FIGS. 12 and 13, the embodiment of FIG. 14 and the embodiment of FIG. 15. As another example, the emissive layer EL of the first emission area EA1 may be located at the same level as that of the embodiment of FIG. 14, the emissive layer EL of the second emission area EA2 may be located at the same level as that of the embodiment of FIG. 15, and the emissive layer EL of the third emission area EA3 may be located at the same level as that of the embodiment of FIGS. 12 and 13.

According to this embodiment, the viewing angle can be adjusted by adjusting the level of the emissive layer EL precisely in each of the emission areas EA1, EA2 and EA3, and the color position on the color coordinates such as CIE 1931 can be adjusted individually.

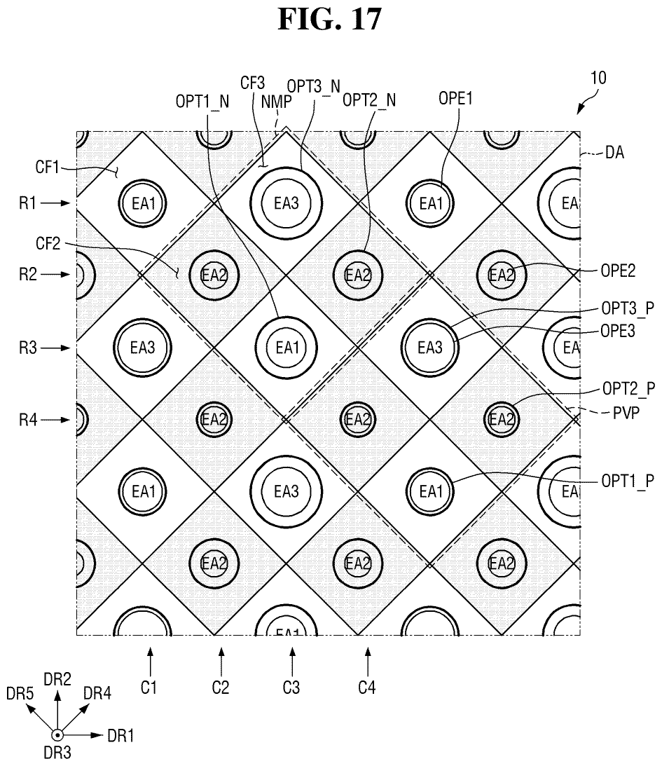

FIG. 17 is a plan view showing arrangement of color filters CF1, CF2 and CF3 in a display area DA of a display device 10 according to an embodiment.

The display device 10 according to the embodiment of FIG. 17 is different from the display device 10 described above with reference to FIG. 9 and the like in that the color filters CF1, CF2 and CF3 have the same area.

More specifically, in the display device 10 according to this embodiment, the areas of the color filters CF1, CF, and CF3 may be all equal. Although not shown in the drawings, adjacent ones of the color filters CF1, CF2 and CF3 may partially overlap each other on the light-blocking layer BM. In addition, the areas of the color filters CF1, CF2 and CF3 may be designed depending on the colors required by the display device 10 or the electronic device 1 so that desired values for the intensity of reflected light from the outside and the colors are obtained.

In the display device 10 according to this embodiment, the first color filter CF1, the second color filter CF2 and the third color filter CF3 may have the same area, and their sides extended in the fourth direction DR4 and the fifth direction DR5 may have the same shape. Accordingly, the first to third color filters CF1, CF2 and CF3 may have the same shape and area regardless of their positions.

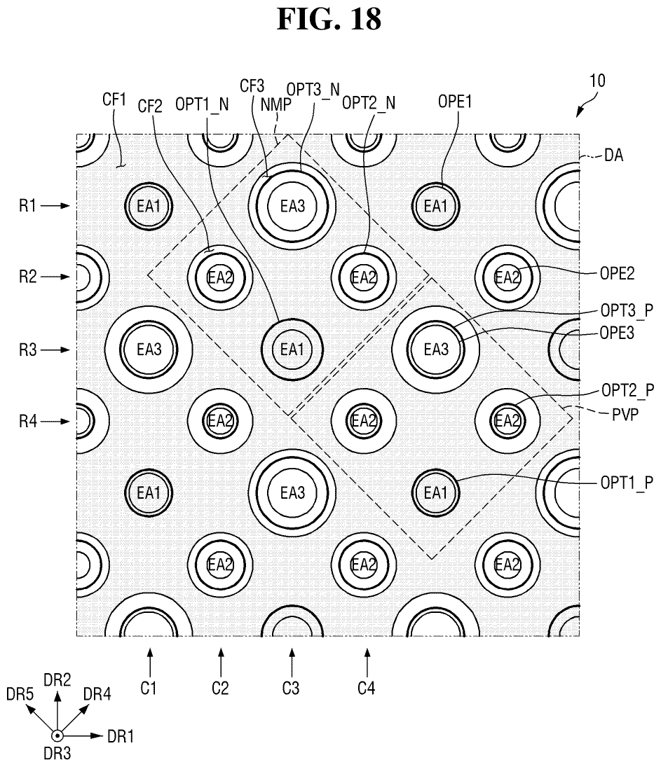

FIG. 18 is a plan view showing arrangement of color filters CF1, CF2 and CF3 in a display area DA of a display device 10 according to an embodiment.

The display device 10 according to the embodiment of FIG. 18 is different from the display device 10 described above with reference to FIG. 9 and the like in that color filters CF1, CF2 and CF3 have different shapes when viewed from the top.

More specifically, in the display device 10 according to this embodiment, the second color filter CF2 and the third color filter CF3 have a circular shape when viewed from the top, and the first color filter CF1 may be disposed entirely on the light-blocking layer BM and the first emission area EA1.

Similar to the embodiment of FIG. 17, the areas of the color filters CF1, CF2 and CF3 may be designed depending on the colors required by the display device 10 or the electronic device 1 so that desired values for the intensity of reflected light from the outside and the colors are obtained.

In concluding the detailed description, those skilled in the art will appreciate that many variations and modifications can be made to the embodiments without substantially departing from the principles of the present disclosure. Therefore, the disclosed embodiments are used in a generic and descriptive sense only and not for purposes of limitation.

What is claimed is:

1. A display device comprising:
a first pixel and a second pixel spaced apart from each other,
wherein each of the first pixel and the second pixel comprises:
a plurality of emission areas where light-emitting elements are disposed;
a light-blocking layer, comprising a plurality of holes overlapping with the emission areas, and disposed between adjacent ones of the emission areas; and
a plurality of color filters disposed in the holes of the light-blocking layer and overlapping with the emission areas,
wherein the emission areas comprise first, second, and third emission areas spaced apart from one another, and
wherein the light-emitting element disposed in the first emission area of the first pixel is located at a lower level than the light-emitting element disposed in the first emission area of the second pixel.

2. The display device of claim 1, wherein a distance between the light-emitting element disposed in the first emission area of the first pixel and the light-blocking layer is greater than a distance between the light-emitting element disposed in the first emission area of the second pixel and the light-blocking layer.

3. The display device of claim 2, wherein the holes of the light-blocking layer comprise first, second, and third holes overlapping with the first, second, and third emission areas, respectively, and
wherein a width of the first hole of the first pixel is smaller than a width of the first hole of the second pixel.

4. The display device of claim 1, further comprising:
a thin-film transistor layer configured to drive the light-emitting elements;
a first protective film disposed on the thin-film transistor layer; and
a pixel-defining layer disposed on the first protective film and comprising an opening overlapping with a respective emission area of the emission areas, and
wherein the first protective film further comprises a first connection opening connected to the opening of the pixel-defining layer in the first pixel.

5. The display device of claim 4, wherein each of the light-emitting elements comprises an emissive layer, and
wherein the emissive layer is disposed in the first connection opening in the first pixel.

6. The display device of claim 5, wherein the light-emitting element in the second pixel is disposed on the first protective film.

7. The display device of claim 6, wherein the emissive layer in the second pixel is disposed in the opening of the pixel-defining layer.

8. The display device of claim 4, wherein each of the light-emitting elements comprises a first electrode, an emissive layer disposed on the first electrode, and a second electrode disposed on the emissive layer, and
wherein the second electrode covers an inner surface of the first connection opening in the first pixel.

9. The display device of claim 8, further comprising:
a thin-film encapsulation layer disposed on the second electrode,
wherein at least a portion of the thin-film encapsulation layer is disposed in the first connection opening in the first pixel.

10. The display device of claim 4, further comprising:
a second protective film disposed between the first protective film and the thin-film transistor layer,
wherein the second protective film comprises a second connection opening connected to the opening through the first connection opening,
wherein each of the light-emitting elements comprises an emissive layer, and
wherein the emissive layer is disposed in the second connection opening in the first pixel.

11. The display device of claim 1, further comprising:
a thin-film transistor layer configured to drive the light-emitting elements;
a first protective film disposed on the thin-film transistor layer; and
a pixel-defining layer disposed on the first protective film and comprising an opening overlapping with a respective emission area of the emission areas,
wherein the first protective film comprises a valley connected to the opening of the pixel-defining layer in the first pixel.

12. The display device of claim 11, wherein each of the light-emitting elements comprises an emissive layer, and
wherein the emissive layer is disposed in the valley in the first pixel.

13. The display device of claim 1, wherein the color filters comprise a first color filter overlapping with the first emission area, a second color filter overlapping with the second emission area, and a third color filter overlapping with the third emission area.

14. A display device comprising:
a plurality of emission areas where light-emitting elements are disposed;
a light-blocking layer, comprising a plurality of holes overlapping with the emission areas, and disposed between adjacent ones of the emission areas;
a plurality of color filters disposed in the holes of the light-blocking layer and overlapping with the emission areas,
wherein the emission areas comprise a first emission area and a second emission area spaced apart from each other,
wherein the first emission area and the second emission area emit light of a same color, and
wherein the light-emitting element disposed in the first emission area is located lower than the light-emitting element disposed in the second emission area.

15. The display device of claim 14, wherein a distance between the light-emitting element disposed in the first emission area and the light-blocking layer is greater than a distance between the light-emitting element disposed in the second emission area and the light-blocking layer.

16. The display device of claim 15, wherein the holes in the light-blocking layer comprise a first hole overlapping with the first emission area and a second hole overlapping with the second emission area, and
wherein a width of the first hole is smaller than a width of the second hole.

17. The display device of claim 14, further comprising:
a thin-film transistor layer configured to drive the light-emitting elements;
a first protective film disposed on the thin-film transistor layer; and
a pixel-defining layer disposed on the first protective film and comprising an opening overlapping with a respective emission area of the emission areas,
wherein the first protective film comprises a first connection opening that is overlapping with the first emission area and is connected to the opening of the pixel-defining layer.

18. The display device of claim 17, wherein each of the light-emitting elements comprises an emissive layer, and
wherein the emissive layer overlapping with the first emission area is disposed in the first connection opening.

19. The display device of claim 18, wherein the light-emitting element disposed in the second emission area is disposed on the first protective film.

20. The display device of claim 19, wherein the emissive layer overlapping with the second emission area is disposed in the opening of the pixel-defining layer.

21. The display device of claim 17, wherein each of the light-emitting elements comprises a first electrode, an emissive layer disposed on the first electrode, and a second electrode disposed on the emissive layer, and
wherein at least a part of the second electrode overlapping with the first emission area covers an inner surface of the first connection opening.

22. The display device of claim 21, further comprising:
a thin-film encapsulation layer disposed on the second electrode,
wherein at least a portion of the thin-film encapsulation layer overlapping with the first emission area is disposed in the first connection opening.

23. The display device of claim 17, further comprising:
a second protective film disposed between the first protective film and the thin-film transistor layer,
wherein the second protective film comprises a second connection opening connected to the opening through the first connection opening,
wherein each of the light-emitting elements comprises an emissive layer, and
wherein the emissive layer overlapping with the first emission area is disposed in the second connection opening.

24. The display device of claim 14, further comprising:
a thin-film transistor layer configured to drive the light-emitting elements;
a first protective film disposed on the thin-film transistor layer; and
a pixel-defining layer disposed on the first protective film and comprising an opening overlapping with a respective emission area of the emission areas, and
wherein the first protective film comprises a valley that is overlapping with the first emission area and is connected to the opening of the pixel-defining layer.

25. The display device of claim 24, wherein each of the light-emitting elements comprises an emissive layer, and
wherein the emissive layer overlapping with the first emission area is disposed in the valley.

26. The display device of claim 14, wherein the color filters comprise a first color filter overlapping with the first emission area and a second color filter overlapping with the second emission area, and
wherein the first color filter and the second color filter transmit light of a same color.
